(19) United States
(12) Patent Application Publication
(10) Pub. No.: US 2026/0156808 A1
(43) Pub. Date: Jun. 4, 2026

(54) SEMICONDUCTOR DEVICE, MANUFACTURING METHOD THEREFOR, AND ELECTRONIC APPARATUS

(71) Applicant: BEIJING SUPERSTRING ACADEMY OF MEMORY TECHNOLOGY, Beijing (CN)

(72) Inventor: Zhao LIU, Beijing (CN)

(73) Assignee: BEIJING SUPERSTRING ACADEMY OF MEMORY TECHNOLOGY, Beijing (CN)

(21) Appl. No.: 18/724,308

(22) PCT Filed: Apr. 2, 2024
(86) PCT No.: PCT/CN2024/085571

§ 371 Date: Jun. 26, 2024

(30) Foreign Application Priority Data
Aug. 8, 2023 (CN) 202310986412.6

(51) Int. Cl. H10B 12/00; H10D 1/68; H10D 30/67

(52) U.S. Cl. CPC H10B 12/488; H10B 12/05; H10B 12/482; H10D 1/714; H10D 30/6757

(57) ABSTRACT

A semiconductor device, a manufacturing method therefor, and an electronic apparatus are disclosed. The semiconductor device includes: multiple transistors, distributed in different layers and stacked along a direction perpendicular to a substrate; a word line, penetrating the different layers and extending in the direction perpendicular to the substrate; the transistor includes a first electrode and a semiconductor layer surrounding a sidewall of the word line; the semiconductor layer includes a first groove with an opening facing away from the word line, the first electrode is within the first groove and connected to the semiconductor layer.

### CROSS-REFERENCE TO RELATED APPLICATIONS

The present application is the U.S. national phase of PCT Application No. PCT/CN2024/085571, filed on Apr. 2, 2024, which claims priority to Chinese Patent Application No. 202310986412.6, filed on Aug. 8, 2023, the disclosures of which are hereby incorporated herein by reference in their entireties.

### TECHNICAL FIELD

Embodiments of the present disclosure relate to, but are not limited to, device design and manufacturing in semiconductor technologies, in particular to a semiconductor device, a method for manufacturing the semiconductor device, and an electronic apparatus.

### BACKGROUND

Semiconductor memory may be divided into volatile memory (Random Access Memory (RAM), including Dynamic Random Access Memory (DRAM) and Static Random Access Memory (SRAM), etc.) and non-volatile memory (Read Only Memory (ROM) and non-ROM).

Taking DRAM as an example, conventional known DRAM has multiple repeated “storage cells”, and each storage cell has a capacitor and a transistor. The capacitor may store 1-bit data, and after charging and discharging, amount of charges stored in the capacitor may correspond to binary data “1” and “0”, respectively. The transistor is a switch for controlling the charging and discharging of the capacitor.

In order to reduce costs of products as much as possible, people want to make as many storage cells as possible on a limited substrate. Since Moore's Law came out, the industry has proposed various semiconductor structure designs and process optimizations to meet people's demands for current products.

### SUMMARY

The following is a summary of the subject matter described in detail in this document. This summary is not intended to limit the scope of protection of the claims.

An embodiment of the present disclosure provides a semiconductor device, including:
a plurality of transistors, distributed in different layers and stacked along a direction perpendicular to a substrate;
a word line, penetrating the different layers and extending in the direction perpendicular to the substrate; and
a transistor includes a first electrode, a second electrode and a semiconductor layer surrounding a sidewall of the word line; the semiconductor layer includes a first groove with an opening facing away from the word line, the first electrode is in the first groove and connected to the semiconductor layer, the second electrode is connected to the semiconductor layer, and the first electrode and the second electrode are distributed at intervals in a direction parallel to the substrate.

In some embodiments, a plurality of semiconductor layers of a plurality of transistors in a same column distributed along the direction perpendicular to the substrate are arranged at intervals.

In some embodiments, the semiconductor device further includes: a plurality of bit lines extending in a second direction parallel to the substrate, distributed in different layers and respectively connected to second electrodes of the plurality of transistors; the semiconductor layer of the transistor also surrounds a sidewall of a bit line to which the transistor is connected.

In some embodiments, the semiconductor layer of the transistor is further connected to an end face of the bit line to which the transistor is connected.

In some embodiments, the second electrode and the bit line are connected to form an integrated structure.

In some embodiments, the semiconductor device further includes a gate insulating layer disposed between the sidewall of the word line and the semiconductor layer, and gate insulating layers of a plurality of transistors in a same column distributed along the direction perpendicular to the substrate are connected to form an integrated structure.

In some embodiments, the semiconductor device further includes:
insulating layers and conductive layers sequentially and alternately distributed from bottom to top in the direction perpendicular to the substrate, wherein a conductive layer includes the first electrode and the second electrode; and
a through hole penetrating each of the insulating layers and each of the conductive layers, wherein the word line and the gate insulating layer surrounding the sidewall of the word line are sequentially distributed from inside to outside of the through hole.

In some embodiments, an aperture of a first region of the through hole corresponding to a conductive layer is larger than an aperture of a second region of the through hole corresponding to an insulating layer; and
only a sidewall of the conductive layer is exposed in the through hole, and a sidewall and partial regions of upper and lower surfaces of the insulating layer are exposed in the through hole.

In some embodiments, the first electrode includes a second groove with an opening facing away from the word line.

In some embodiments, the semiconductor device further includes a second capacitor electrode filling the second groove of the first electrode, and a dielectric layer disposed between the second capacitor electrode and the first electrode.

In some embodiments, the semiconductor device further includes a second capacitor electrode, and a dielectric layer disposed between the second capacitor electrode and the first electrode, a contact surface between the dielectric layer and the first electrode is perpendicular to the substrate.

An embodiment of the present disclosure provides an electronic apparatus including the semiconductor device described in any of the above embodiments.

Embodiments of the present disclosure provide a manufacturing method for a semiconductor device including a plurality of transistors distributed in different layers and stacked along a direction perpendicular to a substrate, a word line extending in the direction perpendicular to the substrate and a bit line; a transistor includes a first electrode, a second electrode, a semiconductor layer surrounding a sidewall of the word line and insulated from the word line; and the manufacturing method for the semiconductor device includes:
providing a substrate, sequentially and alternately depositing a first insulating thin film and a sacrificial layer thin film on the substrate to form a stacked structure including a plurality of first insulating thin films and a plurality of sacrificial layer thin films;
forming a through hole penetrating the stacked structure in the direction perpendicular to the substrate, a sidewall of the through hole exposing each of the sacrificial layer thin films, sequentially depositing, in the through hole, a gate insulating thin film and a gate electrode thin film filling the through hole to form gate insulating layers and word lines of the transistors of multiple layers, wherein gate electrodes of the transistors in different layers are a part of the word line;
patterning the stacked structure such that a sacrificial layer forms a preset pattern, the preset pattern includes a first sub-part and a second sub-part connected to the first sub-part, an orthographic projection of the through hole on the substrate is within an outer contour of an orthographic projection of the preset pattern on the substrate, the first sub-part extends in a first direction, the second sub-part extends in a second direction, and the first direction intersects the second direction; and
etching the first sub-part and etching the second sub-part to form a first semiconductor sub-layer and the first electrode in a region where the first sub-part is located and form a second semiconductor sub-layer and the bit line in a region where the second sub-part is located, wherein the first semiconductor sub-layer and the second semiconductor sub-layer form the semiconductor layer of the transistor, the semiconductor layer surrounds the sidewall of the word line, the semiconductor layer includes a first groove with an opening facing away from the word line, the first electrode is in the first groove and connected to the semiconductor layer.

In some embodiments, forming the through hole penetrating the stacked structure in the direction perpendicular to the substrate includes:
forming the through hole penetrating the stacked structure in the direction perpendicular to the substrate by dry etching, wherein the through hole includes a second sub-hole in a first insulating thin film and a first sub-hole in the sacrificial layer thin film; and
wet laterally etching the sacrificial layer thin film such that on a plane parallel to the substrate, an orthographic projection of the second sub-hole of the through hole in the first insulating thin film falls into an orthographic projection of the first sub-hole of the through hole in the sacrificial layer thin film.

In some embodiments, the etching the first sub-part and etching the second sub-part to form the first semiconductor sub-layer and the first electrode in the region where the first sub-part is located and form the second semiconductor sub-layer and the second electrode in the region where the second sub-part is located, includes:
etching and removing the first sub-part and the second sub-part by a single wet etching process; and
sequentially depositing a semiconductor thin film and a conductive thin film in the region where the first sub-part is located and the region where the second sub-part is located to form the semiconductor layer including the first semiconductor sub-layer and the second semiconductor sub-layer, the first electrode, and the bit line.

In some embodiments, the etching the first sub-part and etching the second sub-part to form the first semiconductor sub-layer and the first electrode in the region where the first sub-part is located and form the second semiconductor sub-layer and the second electrode in the region where the second sub-part is located, includes:
etching and removing the first sub-part, sequentially depositing a first semiconductor thin film and a first conductive thin film in the region where the first sub-part is located to form the first semiconductor sub-layer and the first electrode;
etching and removing the second sub-part, and sequentially depositing, in the region where the second sub-part is located, a second semiconductor thin film and a second conductive thin film filling the region where the second sub-part is located to form the second semiconductor sub-layer and the bit line.

In some embodiments, the depositing the first conductive thin film in a the where the first sub-part is located includes:
after the first semiconductor thin film is deposited in the region where the first sub-part is located, depositing a first conductive thin film filling the region where the first sub-part is located on the first semiconductor thin film; or
after the first semiconductor thin film is deposited in the region where the first sub-part is located, depositing a first conductive thin film of a predetermined thickness on the first semiconductor thin film such that the first conductive thin film forms a second groove with an opening facing away from the word line.

Other features and advantages of the present disclosure will be set forth in the following specification, and moreover, partially become apparent from the specification, or are understood by implementing the present disclosure. The objectives and advantages of the present disclosure can be achieved through structures particularly pointed out in the specification and the drawings.

Other aspects may be understood upon reading and understanding the drawings and detailed description.

### BRIEF DESCRIPTION OF THE DRAWINGS

Accompanying drawings are used to provide further understanding of technical solutions of the present disclosure, constitute a part of the specification, and are used to explain the technical solutions together with the embodiments of the present disclosure but not to form limitations on the technical solutions of the present disclosure.

FIG. 1A is a cross-sectional view along an aa′ direction in FIG. 1E. FIG. 1B is a cross-sectional view along a bb′ direction in FIG. 1E. FIG. 1C is a cross-sectional view along a cc′ direction in FIG. 1E. FIG. 1D is a cross-sectional view along a dd′ direction in FIG. 1E. FIG. 1E is a cross-sectional view of a semiconductor device according to an exemplary embodiment along a direction parallel to a substrate. FIG. 1F is a cross-sectional view of a semiconductor device according to another exemplary embodiment along the direction parallel to the substrate.

FIG. 2A is a cross-sectional view along an aa′ direction after a stacked structure is formed according to an exemplary embodiment. FIG. 2B is a cross-sectional view along a bb′ direction after a stacked structure is formed according to an exemplary embodiment. FIG. 2C is a cross-sectional view along a cc′ direction after a stacked structure is formed according to an exemplary embodiment. FIG. 2D is a cross-sectional view along a dd′ direction after a stacked structure is formed according to an exemplary embodiment.

FIG. 3A is a cross-sectional view along an aa′ direction in FIG. 3E. FIG. 3B is a cross-sectional view along a bb′ direction in FIG. 3E. FIG. 3C is a cross-sectional view along a cc′ direction in FIG. 3E. FIG. 3D is a cross-sectional view along a dd′ direction in FIG. 3E. FIG. 3E is a cross-sectional view along a direction parallel to the substrate after a through hole is formed according to an exemplary embodiment.

FIG. 4A is a cross-sectional view along an aa′ direction after a through hole is enlarged according to an exemplary embodiment. FIG. 4B is a cross-sectional view along a bb′ direction after the through hole is enlarged according to an exemplary embodiment. FIG. 4C is a cross-sectional view along a cc′ direction after the through hole is enlarged according to an exemplary embodiment. FIG. 4D is a cross-sectional view along a dd′ direction after the through hole is enlarged according to an exemplary embodiment.

FIG. 5A is a cross-sectional view along an aa′ direction after a gate insulating layer and a gate electrode are formed according to an exemplary embodiment. FIG. 5B is a cross-sectional view along a bb′ direction after a gate insulating layer and a gate electrode are formed according to an exemplary embodiment. FIG. 5C is a cross-sectional view along a cc′ direction after a gate insulating layer and a gate electrode are formed according to an exemplary embodiment. FIG. 5D is a cross-sectional view along a dd′ direction after a gate insulating layer and a gate electrode are formed according to an exemplary embodiment.

FIG. 6A is a cross-sectional view along an aa′ direction in FIG. 6E. FIG. 6B is a cross-sectional view along a bb′ direction in FIG. 6E. FIG. 6C is a cross-sectional view along a cc′ direction in FIG. 6E. FIG. 6D is a cross-sectional view along a dd′ direction in FIG. 6E. FIG. 6E is a cross-sectional view along a direction parallel to the substrate after a first insulating layer and a sacrificial layer are formed according to an exemplary embodiment.

FIG. 7A is a cross-sectional view along an aa′ direction after a third insulating layer is formed according to an exemplary embodiment. FIG. 7B is a cross-sectional view along a bb′ direction after a third insulating layer is formed according to an exemplary embodiment. FIG. 7C is a cross-sectional view along a cc′ direction after a third insulating layer is formed according to an exemplary embodiment. FIG. 7D is a cross-sectional view along a dd′ direction after a third insulating layer is formed according to an exemplary embodiment.

FIG. 8A is a cross-sectional view along an aa′ direction after a capacitor region is exposed according to an exemplary embodiment. FIG. 8B is a cross-sectional view along a bb′ direction after a capacitor region is exposed according to an exemplary embodiment. FIG. 8C is a cross-sectional view along a cc′ direction after a capacitor region is exposed according to an exemplary embodiment. FIG. 8D is a cross-sectional view along a dd′ direction after a capacitor region is exposed according to an exemplary embodiment.

FIG. 9A is a cross-sectional view along an aa′ direction after a part of a sacrificial layer is etched according to an exemplary embodiment. FIG. 9B is a cross-sectional view along a bb′ direction after a part of a sacrificial layer is etched according to an exemplary embodiment. FIG. 9C is a cross-sectional view along a cc′ direction after a part of a sacrificial layer is etched according to an exemplary embodiment. FIG. 9D is a cross-sectional view along a dd′ direction after a part of a sacrificial layer is etched according to an exemplary embodiment.

FIG. 10A is a cross-sectional view along an aa′ direction in FIG. 10E. FIG. 10B is a cross-sectional view along a bb′ direction in FIG. 10E. FIG. 10C is a cross-sectional view along a cc′ direction in FIG. 10E. FIG. 10D is a cross-sectional view along a dd′ direction in FIG. 10E. FIG. 10E is a cross-sectional view along a direction parallel to the substrate after a first semiconductor sub-layer is formed according to an exemplary embodiment.

FIG. 11A is a cross-sectional view along an aa′ direction after a first electrode is formed according to an exemplary embodiment. FIG. 11B is a cross-sectional view along a bb′ direction after a first electrode is formed according to an exemplary embodiment. FIG. 11C is a cross-sectional view along a cc′ direction after a first electrode is formed according to an exemplary embodiment. FIG. 11D is a cross-sectional view along a dd′ direction after a first electrode is formed according to an exemplary embodiment. FIG. 11E is a cross-sectional view along a direction parallel to the substrate after a first electrode is formed according to an exemplary embodiment.

FIG. 12A is a cross-sectional view along an aa′ direction after a dielectric layer and a second capacitor electrode are formed according to an exemplary embodiment. FIG. 12B is a cross-sectional view along a bb′ direction after a dielectric layer and a second capacitor electrode are formed according to an exemplary embodiment. FIG. 12C is a cross-sectional view along a cc′ direction after a dielectric layer and a second capacitor electrode are formed according to an exemplary embodiment. FIG. 12D is a cross-sectional view along a dd′ direction after a dielectric layer and a second capacitor electrode are formed according to an exemplary embodiment.

FIG. 13A is a cross-sectional view along an aa′ direction after a second sub-part is removed according to an exemplary embodiment. FIG. 13B is a cross-sectional view along a bb′ direction after a second sub-part is removed according to an exemplary embodiment. FIG. 13C is a cross-sectional view along a cc′ direction after a second sub-part is removed according to an exemplary embodiment. FIG. 13D is a cross-sectional view along a dd′ direction after a second sub-part is removed according to an exemplary embodiment.

FIG. 14A is a cross-sectional view along an aa′ direction in FIG. 14E. FIG. 14B is a cross-sectional view along a bb′ direction in FIG. 14E. FIG. 14C is a cross-sectional view along a cc′ direction in FIG. 14E. FIG. 14D is a cross-sectional view along a dd′ direction in FIG. 14E. FIG. 14E is a cross-sectional view along a direction parallel to the substrate after a second semiconductor sub-layer and a bit line are formed according to an exemplary embodiment.

FIG. 15A is a cross-sectional view along an aa′ direction after a second sub-part is removed according to an exemplary embodiment. FIG. 15B is a cross-sectional view along a bb′ direction after a second sub-part is removed according to an exemplary embodiment. FIG. 15C is a cross-sectional view along a cc′ direction after a second sub-part is removed according to an exemplary embodiment. FIG. 15D is a cross-sectional view along a dd′ direction after a second sub-part is removed according to an exemplary embodiment.

FIG. 16A is a cross-sectional view along an aa′ direction after a semiconductor layer is formed according to an exemplary embodiment. FIG. 16B is a cross-sectional view along a bb′ direction after a semiconductor layer is formed according to an exemplary embodiment. FIG. 16C is a cross-sectional view along a cc′ direction after a semiconductor layer is formed according to an exemplary embodiment. FIG. 16D is a cross-sectional view along a dd′ direction after a semiconductor layer is formed according to an exemplary embodiment.

FIG. 17A is a cross-sectional view along an aa′ direction in FIG. 17E. FIG. 17B is a cross-sectional view along a bb′ direction in FIG. 17E. FIG. 17C is a cross-sectional view along a cc′ direction in FIG. 17E. FIG. 17D is a cross-sectional view along a dd′ direction in FIG. 17E. FIG. 17E is a cross-sectional view along a direction parallel to the substrate after a first electrode, a second electrode, and a bit line are formed according to an exemplary embodiment.

FIG. 18A is a cross-sectional view along an aa′ direction in FIG. 18E. FIG. 18B is a cross-sectional view along a bb′ direction in FIG. 18E. FIG. 18C is a cross-sectional view along a cc′ direction in FIG. 18E. FIG. 18D is a cross-sectional view along a dd′ direction in FIG. 18E. FIG. 18E is a cross-sectional view along a direction parallel to the substrate after a dielectric layer and a second capacitor electrode are formed according to an exemplary embodiment.

FIG. 19A is a cross-sectional view along an aa′ direction in FIG. 19E. FIG. 19B is a cross-sectional view along a bb′ direction in FIG. 19E. FIG. 19C is a cross-sectional view along a cc′ direction in FIG. 19E. FIG. 19D is a cross-sectional view along a dd′ direction in FIG. 19E. FIG. 19E is a cross-sectional view of a semiconductor device along a direction parallel to the substrate according to an exemplary embodiment.

FIG. 20A is a cross-sectional view along an aa′ direction after a first electrode, a dielectric layer, and a second capacitor electrode are formed according to an exemplary embodiment. FIG. 20B is a cross-sectional view along a bb′ direction after a first electrode, a dielectric layer, and a second capacitor electrode are formed according to an exemplary embodiment. FIG. 20C is a cross-sectional view along a cc′ direction after a first electrode, a dielectric layer, and a second capacitor electrode are formed according to an exemplary embodiment. FIG. 20D is a cross-sectional view along a dd′ direction after a first electrode, a dielectric layer, and a second capacitor electrode are formed according to an exemplary embodiment.

FIG. 21A is a cross-sectional view along an aa′ direction after a second sub-part is removed according to an exemplary embodiment. FIG. 21B is a cross-sectional view along a bb′ direction after a second sub-part is removed according to an exemplary embodiment. FIG. 21C is a cross-sectional view along a cc′ direction after a second sub-part is removed according to an exemplary embodiment. FIG. 21D is a cross-sectional view along a dd′ direction after a second sub-part is removed according to an exemplary embodiment.

FIG. 22A is a cross-sectional view along an aa′ direction in FIG. 22E. FIG. 22B is a cross-sectional view along a bb′ direction in FIG. 22E. FIG. 22C is a cross-sectional view along a cc′ direction in FIG. 22E. FIG. 22D is a cross-sectional view along a dd′ direction in FIG. 22E. FIG. 22E is a cross-sectional view along a direction parallel to the substrate after a second semiconductor sub-layer and a bit line are formed according to an exemplary embodiment.

### DETAILED DESCRIPTION

The embodiments of the present disclosure will be described in detail below with reference to the accompanying drawings. The embodiments in the present application and features in the embodiments may be combined with each other randomly if there is no conflict.

Unless otherwise defined, technical terms or scientific terms used in the present disclosure shall have a general meaning as understood by a person of ordinary skills in the art to which the present disclosure pertains.

An implementation of the present disclosure is not necessarily limited to dimensions shown in the drawings, and the shapes and sizes of the components in the drawings do not reflect actual scales. Further, the drawings schematically illustrate ideal examples, but embodiments of the present disclosure are not limited to shapes or values shown in the drawings.

Ordinal numerals such as “first”, “second” and “third” in the present disclosure are provided to avoid confusion between constituent elements, but do not indicate any order, quantity or importance.

In the present disclosure, for convenience, words or expressions indicating orientation or positional relationship such as “middle”, “upper”, “lower”, “front”, “rear”, “vertical”, “horizontal”, “top”, “bottom”, “inner” and “outer” are employed to explain positional relationship of the constituent elements with reference to the accompanying drawings, they are employed for ease of description of the specification and simplification of the description only, but do not indicate or imply that the referred device or element must have a particular orientation and be constructed and operate in a particular orientation, and therefore cannot be construed as limitations on the present disclosure. The positional relationship of the constituent elements is appropriately changed according to a direction in which various constituent elements are described. Therefore, the present disclose is not limited to the words or expressions described in the present disclosure, and replacement may be appropriately made according to the situation.

In the present disclosure, terms “mount”, “couple” and “connect” should be understood broadly, unless otherwise expressly specified and defined. For example, a connection may be a physical connection or a signal connection; it may be a contact connection or an integrated connection; it may be a direct connection, indirect connection through middleware, or internal communication between two elements. For those of ordinary skills in the art, the specific meaning of the above terms in the present disclosure may be understood according to actual situations.

In the present disclosure, a transistor refers to an element including at least three terminals, i.e., a gate electrode, a drain electrode, and a source electrode. A transistor has a channel region between a drain electrode (drain electrode terminal, drain region, or drain) and a source electrode (source electrode terminal, source region, or source), and a current can flow through the drain electrode, the channel region, and the source electrode. In the present disclosure, the channel region refers to the region through which the current mainly flows.

In the present disclosure, the first electrode may be a drain electrode and the second electrode may be a source electrode, or the first electrode may be a source electrode and the second electrode may be a drain electrode. In cases that transistors with opposite polarities are used, or a current direction changes during working of a circuit, or the like, functions of the “source electrode” and the “drain electrode” may sometimes be exchanged. Therefore, in the present disclosure, the “source electrode” and the “drain electrode” are interchangeable.

In the present disclosure, a “connection” includes a case where constituent elements are connected together through an element having a certain electrical effect. There is no special restriction on “elements with certain electrical effects” as long as they can transmit and receive electrical signals between connected constituent elements. Examples of “elements having certain electrical effects” include not only electrodes and wirings, but also switching elements (such as transistors), resistors, inductors, capacitors, and other elements having various functions, etc.

In the present disclosure, “parallel” refers to approximately parallel or almost parallel, for example, a state in which the angle formed by two straight lines is −10 degrees or more and 10 degrees or less, and therefore further includes a state in which the angle is −5 degrees or more and 5 degrees or less. In addition, “perpendicular” refers to “approximately perpendicular”, for example, a state in which the angle formed by two straight lines is 80 degrees or more and 100 degrees or less, and therefore further includes a state in which the angle is 85 degrees or more and 95 degrees or less.

“A and B are arranged in a same layer” described in the present disclosure includes a film layer of a same material or a film layer formed of different materials on a same film layer. Exemplarily, A and B are formed into a same film layer from a same material and then are formed by a same patterning process or different patterning processes. A and B arranged in the same layer may be on a same horizontal plane but not necessarily on the same film layer, or on different regions of the same film layer but not necessarily on the same horizontal plane.

“An orthographic projection of B is within a range of an orthographic projection of A” in embodiments of the present disclosure means that a boundary of the orthographic projection of B falls within the boundary range of the orthographic projection of A, or the boundary of the orthographic projection of A overlaps with the boundary of the orthographic projection of B.

“A and B are of an integrated structure” in embodiments of the present disclosure may mean that there is no obvious boundary interface, such as obvious faultage or gaps, viewed from microstructure. Generally, connected film layers formed by patterning on one film layer are of an integrated structure. For example, A and B form one film layer using the same material and simultaneously form a structure with a connection relationship through the same patterning process.

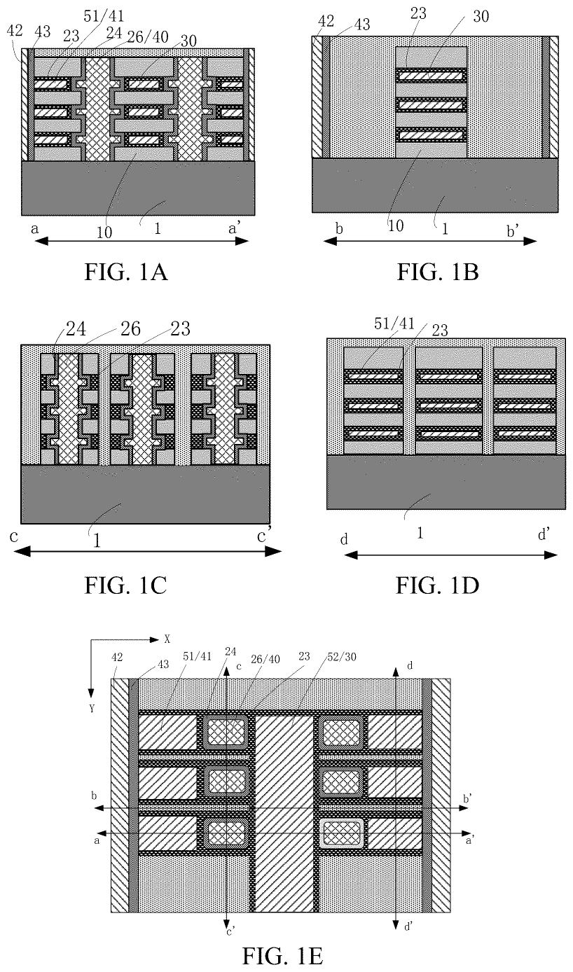

FIG. 1A is a cross-sectional view along an aa′ direction in FIG. 1E, FIG. 1B is a cross-sectional view along a bb′ direction in FIG. 1E, FIG. 1C is a cross-sectional view along a cc′ direction in FIG. 1E, FIG. 1D is a cross-sectional view along a dd′ direction in FIG. 1E, FIG. 1E is a cross-sectional view of a semiconductor device according to an exemplary embodiment along a direction parallel to the substrate 1. The semiconductor device may be a transistor, or a storage cell including a transistor, or a storage cell array including storage cells, or a 3D stacked structure including a storage cell array, or a memory including a transistor or a storage cell array, etc.

As shown in FIGS. 1A to 1E, embodiments of the present disclosure provide a semiconductor device including:
a plurality of transistors, distributed in different layers and stacked along a direction perpendicular to a substrate 1; and
a word line 40, penetrating the different layers and extending in the direction perpendicular to the substrate 1.

The transistor may include a first electrode 51, a second electrode 52, and a semiconductor layer 23 surrounding a sidewall of the word line 40. The semiconductor layer 23 may include a first groove with an opening facing away from the word line 40, the first electrode 51 is within the first groove and connected to the semiconductor layer 23. That is, the first electrode 51 includes an end face facing the word line 40 and a sidewall connected to the end face, and the semiconductor layer 23 is connected to the end face and surrounds the sidewall of the first electrode 51.

In a scheme according to this embodiment, the first electrode 51 is provided in the first groove of the semiconductor layer 23. When the transistor is manufactured to form a stacked structure, a conductive thin film may not be deposited, after a gate electrode is manufactured by etching the stacked structure, the conductive thin film can be deposited to manufacture the first electrode. A film layer that is easy to be etched can be used to occupy the film layer where a conductive thin film is located, which makes the etching more controllable and facilitates replacing a different conductive film as the first electrode without changing processes, and is beneficial for iterative updating of the device.

In some embodiments, the transistor may further include a gate electrode 26, and gate electrodes 26 of transistors of different layers may be a part of the word line 40. It will be appreciated that there is no need to make a separate gate electrode 26 before and after the word line 40 is formed, wherein a part of the word line 40 acts as the gate electrode 26 after the word line 40 is made. Herein, a local profile of the word line 40 is not defined, and the word line 40 extends as a whole in the direction perpendicular to the substrate 1. Locally, corresponding to each transistor, the gate electrode 26 in this region may extend in a horizontal direction and a vertical direction, but the semiconductor layer 23 is formed on the sidewall of the word line 40, and a region in the sidewall of the word line 40 where the semiconductor layer 23 is wrapped may be formed by that the main surface of the film layer includes a region extending along the direction perpendicular to the substrate 1, or includes a region extending in a horizontal direction in addition to the region extending along the direction perpendicular to the substrate 1.

In some embodiments, the gate electrode 26 may be linear and extend as a whole only in the direction perpendicular to the substrate 1. The word line 40 formed by the gate electrode 26 or a plurality of gate electrodes 26 includes a side surface. The side surface is adjacent to a sidewall of a hole where the word line 40 is located, and the side surface is perpendicular to the substrate 1 as a whole, or the film layer in a partial region of the side wall corresponding to the semiconductor layer 23 that plays the role of gate electrode control is perpendicular to the substrate 1. Regions where bending may exist locally during actual manufacturing of the product are also included in the cases described above in the present application.

Herein, “surrounding” may be understood as partially or completely surrounding the word line 40. In some embodiments, the “surrounding” may be overall entirely surrounding, and a cross-section of the semiconductor layer 23 after the surrounding is in a shape of a closed ring. The cross-section is taken along a direction parallel to the substrate 1. In some embodiments, the surrounding may be partially surrounding, and the cross-section after the surrounding is not closed, but has a shape of a ring, e.g., a ring with an opening.

In an exemplary embodiment, material composition of different regions of the word line 40 extending in the direction perpendicular to the substrate 1 is the same, which can be understood that the word line 40 is formed using a same deposition process, and the material composition being the same can be understood as that main elements tested in the material are the same, for example, the regions are all formed through metals, alloys, metal nitrides, metal oxides (such as ITO, IZO, etc.), and metal silicides, while atomic number ratios of different regions of the word line 40 are not limited.

In some embodiments, a cross-section of the gate electrode 26 in the direction parallel to the substrate 1 is, for example, in a shape such as a square, but the embodiment of the present disclosure is not limited thereto, and may be in other shapes, such as a circle or the like.

In some embodiments, the first electrode 51 and the second electrode 52 of a same transistor may be on a same horizontal plane.

In some embodiments, the first electrode 51 and the second electrode 52 may be provided in a same layer. That is, the first electrode 51 and the second electrode 52 can be formed simultaneously by a same process, but the embodiment of the present disclosure is not limited thereto, and the first electrode 51 and the second electrode 52 can be respectively manufactured by different processes.

In some embodiments, the first electrode 51 may extend in the first direction X.

In some embodiments, the first direction X may be parallel to the substrate 1.

In some embodiments, transistors stacked in different layers may share one word line 40 extending in the direction perpendicular to the substrate 1.

In some embodiments, a plurality of semiconductor layers 23 of the plurality of transistors may be arranged at intervals, e.g. physically disconnected from each other. That is, semiconductor layers 23 of different layers are not connected to each other, which can eliminate parasitic transistors, and avoid leakage of transistors between layers. The plurality of transistors may be a plurality of transistors of a same column distributed in the direction perpendicular to the substrate 1.

In some embodiments, the semiconductor device may further include: a plurality of bit lines 30 extending in a second direction Y and connected to second electrodes 52 of the plurality of transistors respectively. A semiconductor layer 23 of a transistor also surrounds sidewalls of a bit line 30 to which the transistor is connected. The bit line 30 extends in the second direction Y, and the sidewall of the bit line 30 is a surface of the bit line 30 that extends in the second direction Y.

In some embodiments, the second direction Y may be parallel to the substrate 1.

In some embodiments, the second direction Y and the first direction X may intersect.

In some embodiments, the first direction X and the second direction Y are perpendicular to each other.

In some embodiments, a second electrode 52 and a bit line 30 may be connected to form an integrated structure. For example, the bit line 30 is a straight line, a sidewall of which is connected to the semiconductor layer 23, or the bit line 30 has an integrally designed branch, and the branch is connected to the semiconductor layer 23. An extension direction of the branch intersects, e.g., is approximately perpendicular to, an extension direction of the bit line 30. The branch may be multiple branches on a sidewall of the bit line 30 or multiple branches on two sidewalls of the bit line 30, each of the branches corresponds to formation of a transistor or a storage cell.

In some embodiments, the semiconductor layer 23 may also be in contact with an end face of the bit line 30.

A shape of the bit line 30 shown in FIG. 1E is an example only, and the shape of the bit line 30 is not limited thereto, for example, the bit line 30 may be in a shape shown in FIG. 1F, and so on.

In some embodiments, the semiconductor device may further include a gate insulating layer 24 disposed between a sidewalls of the word line 40 and the semiconductor layer 23, and the gate insulating layers 24 of the plurality of transistors in a same column distributed in the direction perpendicular to the substrate 1 may be connected to form an integrated structure.

In some embodiments, transistors of different layers may share a ring-shaped gate insulation layer 24 extending along the direction perpendicular to the substrate 1.

In some embodiments, the semiconductor device may further include:
insulating layers and conductive layers sequentially and alternately distributed from bottom to top in the direction perpendicular to the substrate 1, wherein a conductive layer includes the first electrode 51 and the second electrode 52; and
a through hole penetrating each of the insulating layers and each of the conductive layers, the word line 40 and the gate insulating layer 24 surrounding the sidewall of the word line 40 are sequentially distributed from the inside to the outside of the through hole. That is to say, after the through hole is formed by etching, film layers can be deposited respectively to form the word lines 40 and the gate insulating layers 24 of the transistors of multiple layers, thereby simplifying the process.

In some embodiments, an aperture of a first region of the through hole corresponding to a conductive layer is larger than an aperture of a second region of the through hole corresponding to an insulating layer.

Only a sidewall of the conductive layer is exposed in the through hole, and a sidewall and partial regions of upper and lower surfaces of the insulating layer are exposed in the through hole.

In some embodiments, as shown in FIG. 1E, a cross-section of the first electrode 51 in a direction parallel to the substrate 1 may be square. A surface of the first electrode 51 away from the word line 40 may be perpendicular to the substrate 1. The semiconductor device may further include a second capacitor electrode 42, and a dielectric layer 43 disposed between the second capacitor electrode 42 and the first electrode 51, and a contact surface between the dielectric layer 43 and the first electrode 51 may be perpendicular to the substrate 1. In this embodiment, the first electrode 51 may have a solid structure without an opening.

In some embodiments, an opening may be provided on a side of the first electrode 51 away from the word line 40. That is, the first electrode 51 includes a second groove with an opening facing away from the word line 40. In this embodiment, when the first electrode 51 is an electrode of the capacitor, arrangement of the second groove can increase an area of the first electrode 51, thereby increasing a capacitance value.

In some embodiments, a cross-section of the second groove may be U-shaped in a direction parallel to the opening of the second groove and in the direction perpendicular to the substrate 1, and the cross-section of the second groove may be U-shaped in the direction parallel to the substrate 1. Subsequently, the dielectric layer 43 and the second capacitor electrode 42 are deposited and formed in the second groove to form a capacitor. Embodiments of the present disclosure are not limited thereto, and the second groove of the first electrode 51 may be in other shapes.

In some embodiments, as shown in FIG. 1E, storage cells in a same layer form an array distributed in the first direction X and the second direction Y respectively, and each layer of the storage cells further includes a bit line 30, wherein the bit line 30 is connected to a second electrode 52 of transistors in a same column and in the same layer. FIG. 1E shows that each layer includes three rows and two columns of storage cells, but the embodiment of the present disclosure is not limited thereto, and each layer may include other rows and columns of storage cells, for example, may include only one storage cell. In some embodiments, the semiconductor device may further include a data storage element. The stacked transistors described above can be applied in a plurality of scenarios in memory, such as a conventional 1T structure, a 2T structure, a structure with capacitance, or a structure without capacitance in a DRAM scenario. Optionally, it can be applied in a 4T or 6T storage cell scenario in SRAM.

In some embodiments, the data storage element is, for example, a capacitor, that is, a 1T1C storage structure is formed. However, embodiments of the present disclosure are not limited thereto, and a 2T0C storage structure can be formed with other transistors, and so on.

In some embodiments, the capacitor may include a first capacitor electrode 41 and a second capacitor electrode 42, and the first capacitor electrode 41 is connected to the first electrode 51.

In some embodiments, the first capacitor electrode 41 and the first electrode 51 may be an integrated structure, that is, a same electrode is simultaneously used as the first capacitor electrode 41 and the first electrode 51.

In some embodiments, as shown in FIGS. 1A to 1E, the second capacitor electrode 42 may be a planar electrode extending in the direction perpendicular to the substrate 1.

In some embodiments, as shown in FIGS. 1A to 1E, the dielectric layer 43 may be a planar film layer extending in the direction perpendicular to the substrate 1.

In some embodiments, the semiconductor device may further include a second capacitor electrode 42 that fills the second groove of the first electrode 51, and a dielectric layer 43 disposed between the second capacitor electrode 42 and the first electrode 51.

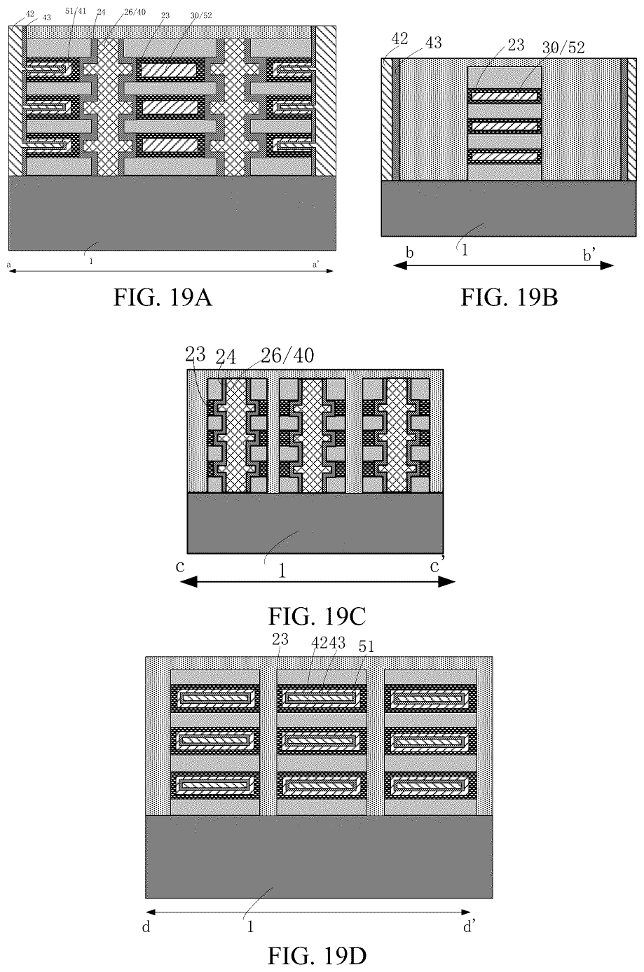

FIGS. 19A to 19E are schematic views of a semiconductor device according to another exemplary embodiment, among them, FIG. 19A is a cross-sectional view along an aa′ direction in 19E, FIG. 19B is a cross-sectional view along a bb′ direction in FIG. 19E, FIG. 19C is a cross-sectional view along a cc′ direction in FIG. 19E, FIG. 19D is a cross-sectional view along a dd′ direction in FIG. 19E, and FIG. 19E is a cross-sectional view of a semiconductor device along a direction parallel to the substrate 1 according to an exemplary embodiment. As shown in FIGS. 19A to 19E, in this embodiment, the first electrode 51 has a U-shaped second groove, an opening direction of the U-shaped second groove faces away from the word line 40, and accordingly, the second capacitor electrode 42 may include a vertical part extending in a direction perpendicular to the substrate 1 and a protruding part extending from the vertical part into the second groove. The protruding part fills the second groove (the protruding part fills a region in the second groove that is not occupied by the dielectric layer 43). The first electrode 51 and the second capacitor electrode 42 are insulated by the dielectric layer 43 provided between them. The scheme according to this embodiment can increase an area of the electrode of the capacitor and increase a capacitance value.

In some embodiments, second capacitor electrodes 42 of capacitors connected to transistors of different layers in a same column may be connected to form an integrated structure. As shown in FIG. 1A, main surfaces of second capacitor electrodes 42 of capacitors of different layers in a first column extend in the direction perpendicular to the substrate 1 to form a plate. As shown in FIG. 19A, the main surfaces of the second capacitor electrodes 42 of the capacitors of different layers in the first column extend in the direction perpendicular to the substrate 1 to form a plate, and a protruding part is provided on the plate-like film layer to fill an opening of a first electrode 51 to form a capacitor with the first electrode 51.

In some embodiments, second capacitor electrodes 42 of capacitors connected to transistors in a same column and in a same layer may be connected to form an integrated structure.

In some embodiments, projections of first electrodes 51 of transistors adjacent in the direction perpendicular to the substrate 1 in the direction parallel to the substrate 1 may coincide with each other, projections of the second electrodes 52 in the direction parallel to the substrate 1 may coincide with each other, and projections of gate electrodes 26 in the direction parallel to the substrate 1 may coincide with each other. According to the scheme provided by this embodiment, during a process, a region where the first electrodes and the second electrodes are stacked in multiple layers can be formed by a mask pattern, and the realization process is simple. In addition, the structure of the semiconductor device can be made more compact.

In some embodiments, the semiconductor device may further include an insulating thin film layer filled between different transistors.

Technical solutions of the embodiments will be further explained through a manufacturing process of the semiconductor device of the embodiment. A “patterning process” mentioned in the embodiments includes film layer deposition, photoresist coating, mask exposure, development, etching, photoresist stripping, and other treatments, and is a mature manufacturing process in related technologies. A “photolithography process” in the embodiments includes film layer coating, mask exposure, and development, and is a mature manufacturing process in the related technologies. Known processes such as sputtering, evaporation, chemical vapor deposition may be used for the deposition, known coating processes may be used for the coating, and known approaches may be used for etching, which are not specifically limited here. In description of the embodiments, it should be understood that a “thin film” refers to a layer of thin film made of a certain material on a substrate using a deposition or coating process. If the “thin film” does not need a patterning process or photolithography process during the whole manufacturing process, the “thin film” may also be called a “layer”. If the “thin film” needs a patterning process or photolithography process during the whole manufacturing process, it is called a “thin film” before the patterning process and a “layer” after the patterning process. The “layer” after the patterning process or photolithography process contains at least one “pattern”.

In some embodiments, a manufacturing process of the semiconductor device may include following:

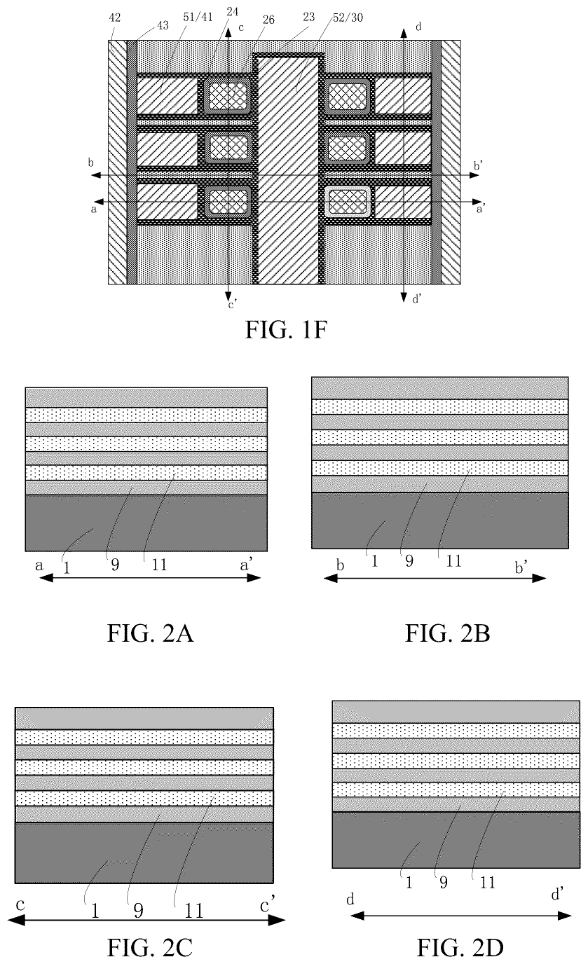

101) Sequentially and alternately depositing first insulating thin films 9 and sacrificial layer thin films 11 on a substrate 1 to form a laminated structure, as shown in FIGS. 2A, 2B, 2C and 2D, FIG. 2A is a cross-sectional view along an aa′ direction, FIG. 2B is a cross-sectional view along a bb′ direction, FIG. 2C is a cross-sectional view along a cc′ direction, and FIG. 2D is a cross-sectional view along a dd′ direction.

In some embodiments, the first insulating thin films 9 may be low-K dielectric layers, i.e., dielectric layers having a dielectric constant K<3.9, a material of which include, but is not limited to, a silicon oxide such as silicon dioxide (SiO2), etc.

In some embodiments, a sacrificial layer thin film 11 may include a film layer that has a larger etching selectivity ratio than the first insulating thin film 9, and a material of the sacrificial layer thin film 11 includes but is not limited to SiN (silicon nitride). In this embodiment, no conductive thin film is deposited when the laminated structure is manufactured, and when the laminated structure is etched in a subsequent process, a smooth and vertical surface may be formed more easily than the laminated structure formed by etching an insulating thin film and a conductive thin film, the device structure can be better controlled, and device performance is more stable.

The laminated structure shown in FIGS. 2A to 2D includes four layers of the first insulating thin films 9 and three layers of the sacrificial layer thin films 11, by way of example only, and in other embodiments, the laminated structure may include more or fewer layers of the first insulating thin films 9 and the sacrificial layer thin films 11 alternately arranged.

102) Forming a through hole K1;

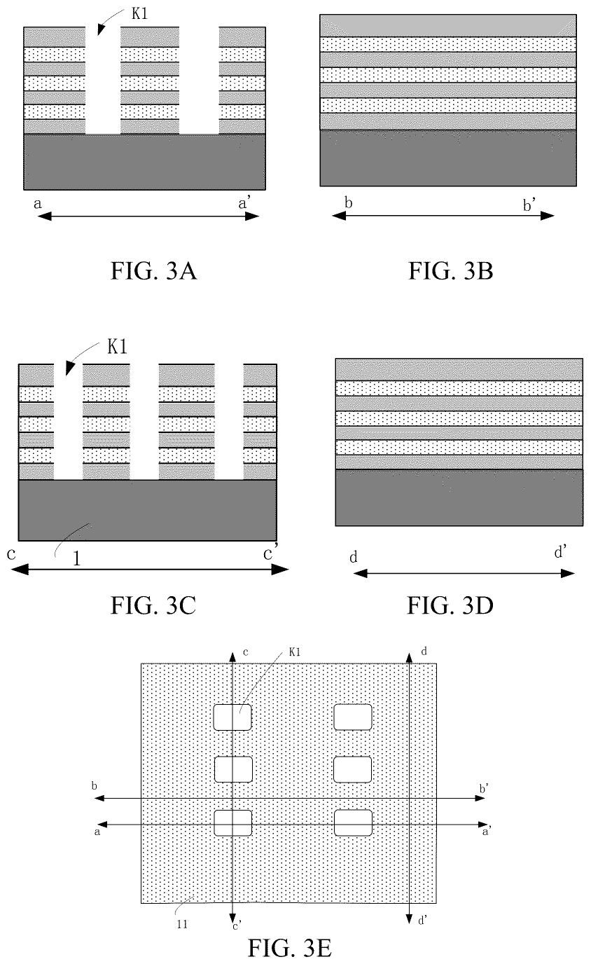

The forming the through hole K1 may include:
Etching the laminated structure to form a plurality of through holes K1 penetrating the laminated structure, as shown in FIGS. 3A, 3B, 3C, 3D and 3E. Among them, FIG. 3A is a cross-sectional view along an aa′ direction, FIG. 3B is a cross-sectional view along a bb′ direction, FIG. 3C is a cross-sectional view along a cc′ direction, FIG. 3D is a cross-sectional view along a dd′ direction, and FIG. 3E is a cross-sectional view in a direction parallel to the substrate 1 after through holes K1 are formed according to an exemplary embodiment.

In some embodiments, the laminated structure may be etched by dry etching. For example, carbon tetrafluoride (CF4) or difluoromethane (CH2F2) may be used for etching.

In some embodiments, the through holes K1 may extend in a direction perpendicular to the substrate 1.

In some embodiments, an orthographic projection of a through hole K1 on a plane parallel to the substrate 1 may be square. However, embodiments of the present disclosure are not limited thereto, and the orthographic projection may be circular, oval, etc.

In some embodiments, the plurality of through holes K1 may be distributed in an array so as to subsequently form transistors distributed in an array.

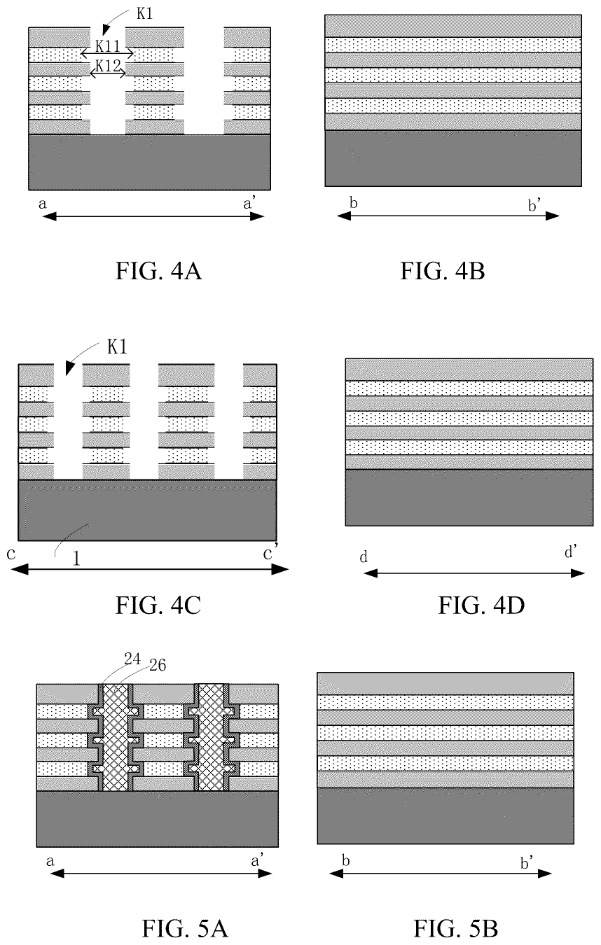

103) Enlarging a region where the through hole K1 is located in a sacrificial layer thin film 11;
The enlarging the region where the through hole K1 is located in the sacrificial layer thin film 11 may include laterally etching the sacrificial layer thin film 11 to enlarge the region where the through hole K1 is located in the sacrificial layer thin film 11, as shown in FIGS. 4A, 4B, 4C, and 4D. Among them, FIG. 4A is a cross-sectional view along an aa′ direction, FIG. 4B is a cross-sectional view along a bb′ direction, FIG. 4C is a cross-sectional view along a cc′ direction, and FIG. 4D is a cross-sectional view along a dd′ direction. At this time, an orthographic projection of a second sub-hole K12 of the through hole K1 in a first insulating thin film 9 on the substrate 1 falls into an orthographic projection of a first sub-hole K11 of the through hole K1 in the sacrificial layer thin film 11 on the substrate 1. Since the sacrificial layer thin film 11 is to be etched off during a subsequent manufacturing process, and the film layer in the through hole K1 is retained, enlarging the through hole K1 in the sacrificial layer thin film 11 can increase an area of the retained film layer, and can enhance support of the film layer.

In some embodiments, the sacrificial layer thin film 11 close to the through hole K1 can be oxidized and then etched, and etching the oxidized sacrificial layer thin film 11 is better controlled than directly etching the sacrificial layer thin film 11.

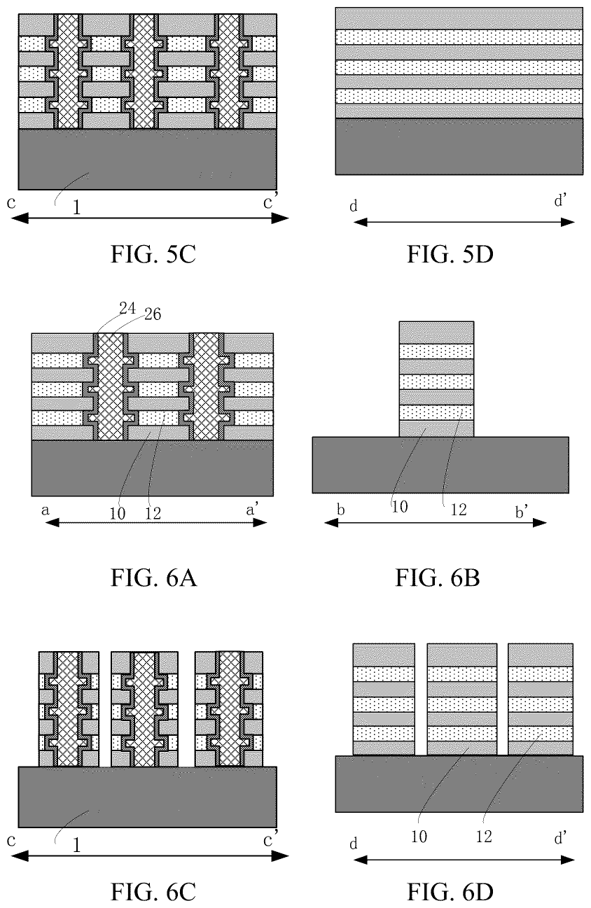

104) Forming a gate insulating layer 24 and a gate electrode 26;
The forming the gate insulating layer 24 and the gate electrode 26 may include sequentially depositing, in the through hole K1, a gate insulating thin film and a gate electrode thin film filling the through hole K1 to form the gate insulating layer 24 and the gate electrode 26, as shown in FIGS. 5A, 5B, 5C, and 5D. Among them, FIG. 5A is a cross-sectional view along an aa′ direction, FIG. 5B is a cross-sectional view along a bb′ direction, FIG. 5C is a cross-sectional view along a cc′ direction, and FIG. 5D is a cross-sectional view along a dd′ direction.

In some embodiments, gate electrodes 26 of transistors at the same position in different layers are connected to form the word line 40.

In some embodiments, the gate electrode 26 may extend in the direction perpendicular to the substrate 1. The gate insulating layer 24 surrounds a sidewall of the gate electrode 26.

In an exemplary embodiment of the present disclosure, a material of the gate insulating layer 24 may include one or more layers of High-K dielectric material, such as a dielectric material with a dielectric constant K≥3.9. In some embodiments, the material may include one or more oxides of hafnium, aluminum, lanthanum, zirconium and the like. For example, the material may include, but is not limited to, at least one of the following: hafnium oxide (HfO2), alumina (Al2O3), hafnium aluminum oxide (HfAlO), hafnium lanthanum oxide (HfLaO), zirconium oxide (ZrO2) and other high-K materials.

In an exemplary embodiment, the gate electrode thin film may be of one or more of the following different types of materials:
For example, a material of the gate electrode thin film may be a metal, such as tungsten, aluminum, titanium, copper, nickel, platinum, ruthenium, molybdenum, gold, iridium, rhodium, tantalum, cobalt and the like; or may be a metal alloy containing metals of these metals mentioned above.

Optionally, the material of the gate electrode thin film may also be metal oxide, metal nitride, metal silicide and metal carbide, for example, a metal oxide material with high conductivity such as indium tin oxide (ITO), indium zinc oxide (IZO) and indium oxide (InO); for example, a metal nitride material such as titanium nitride (TiN), tantalum nitride (TaN), tungsten nitride (WN) and titanium aluminum nitride (TiAlN).

Optionally, for example, the material of the gate electrode thin film may be a polysilicon material, a conductive doped semiconductor, or the like, such as, conductive doped silicon, conductive doped germanium, conductive doped silicon germanium, etc., or another material that shows conductivity, etc.

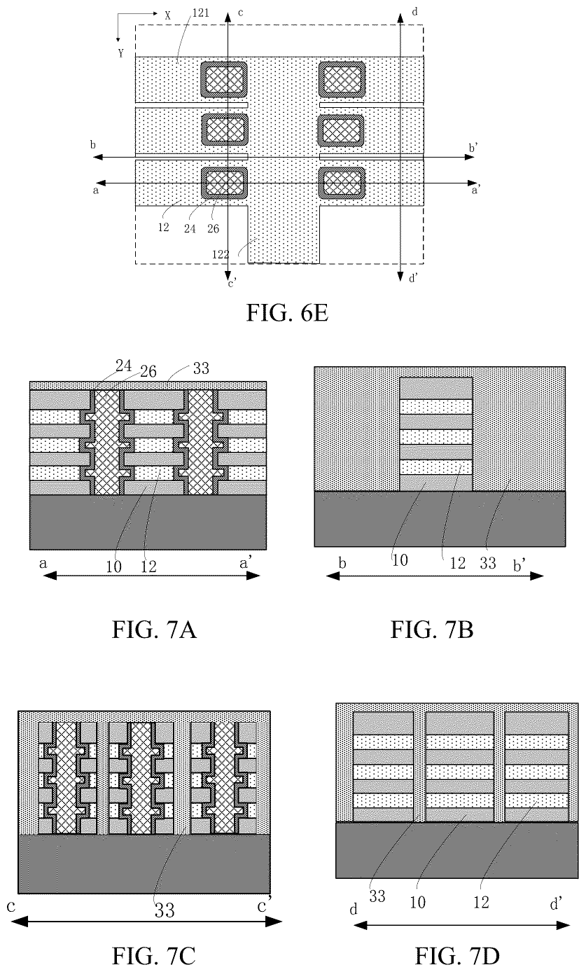

105) Patterning the first insulating thin film 9 and the sacrificial layer thin film 11 to form the first insulating layer 10 and the sacrificial layer 12, as shown in FIGS. 6A, 6B, 6C, 6D and 6E. Among them, FIG. 6A is a cross-sectional view along an aa′ direction, FIG. 6B is a cross-sectional view along a bb′ direction, FIG. 6C is a cross-sectional view along a cc′ direction, and FIG. 6D is a cross-sectional view along a dd′ direction. FIG. 6E is a cross-sectional view (taken at a film layer where the sacrificial layer 12 is located) in the direction parallel to the substrate 1. The dashed line in FIG. 6E illustrates a boundary of the sacrificial layer thin film 11 before it is etched.

In this step, the pattern of the sacrificial layer 12 may be determined according to shapes of the first electrode 51, the second electrode 52 and the bit line 30 of the transistor. In some embodiments, in a cross-section parallel to the substrate 1, the pattern of the sacrificial layer 12 may be as shown in FIG. 6E. After the sacrificial layer 12 is subsequently removed, the semiconductor layer 23, the first electrode 51, the second electrode 52, and the bit line 30 of the transistor may be formed in the region where the sacrificial layer 12 is located.

In some embodiments, the sacrificial layer 12 may include a first sub-part 121 extending in the first direction X and a second sub-part 122 extending in the second direction Y. A region where the first sub-part 121 is located may subsequently form the first electrode 51 of the transistor, a region where the second sub-part 122 is located may subsequently form the second electrode 52 of the transistor, as well as form the word line 30.

In some embodiments, the laminated structure may be etched in the direction perpendicular to the substrate 1 by dry etching to form the first insulating layer 10 and the sacrificial layer 12.

106) Forming a third insulating layer 33;
The forming the third insulating layer 33 includes: depositing a third insulating thin film on the substrate 1 on which the above-mentioned structures are formed and grinding the third insulating thin film to form a third insulating layer 33, wherein the third insulating layer 33 fills regions where the first insulating thin film 9 and the sacrificial layer thin film 11 etched off in step 104 are located, and the third insulating layer 33 covers the laminated structure, as shown in FIGS. 7A, 7B, 7C and 7D. Among them, FIG. 7A is a cross-sectional view along an aa′ direction, FIG. 7B is a cross-sectional view along a bb′ direction, FIG. 7C is a cross-sectional view along a cc′ direction, and FIG. 7D is a cross-sectional view along a dd′ direction.

In some embodiments, the third insulating thin film may be a low-K dielectric layer, a material of which includes but is not limited to a silicon oxide such as silicon dioxide (SiO2), etc.

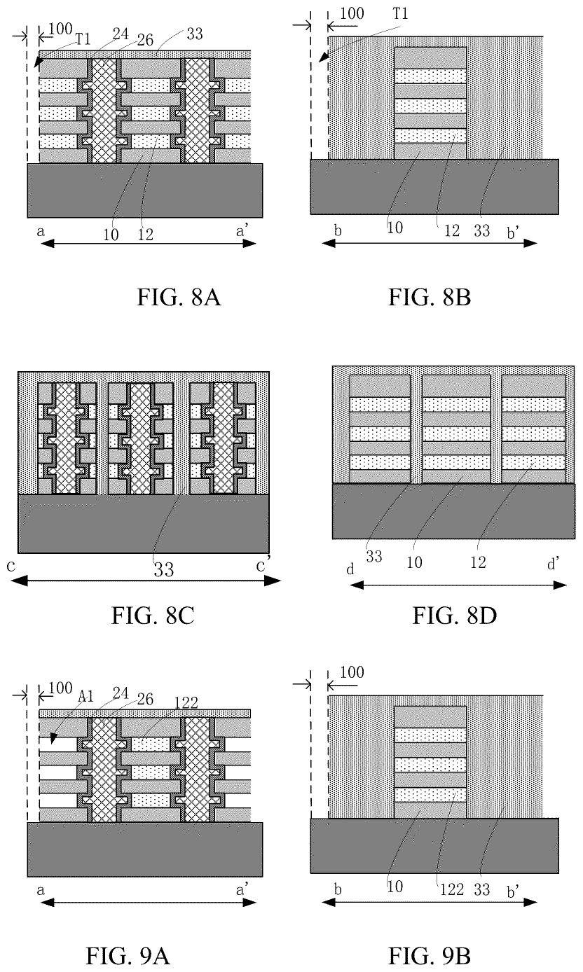

107) Exposing a capacitor region 100;
The exposing the capacitor region 100 may include: patterning the laminated structure, etching and removing film layers in the capacitor region 100, to form a first trench T1, as shown in FIGS. 8A, 8B, 8C, and 8D. Among them, FIG. 8A is a cross-sectional view along an aa′ direction, FIG. 8B is a cross-sectional view along a bb′ direction, FIG. 8C is a cross-sectional view along a cc′ direction, and FIG. 8D is a cross-sectional view along a dd′ direction. A capacitor may be formed subsequently in the capacitor region 100. Capacitor regions 100 may be provided on two sides of the laminated structure to form capacitors connected to different transistors respectively. The capacitor region 100 may be provided on one side of the laminated structure and expose an end face of the first sub-part 121. The first trench T1 extends in the second direction Y.

In some embodiments, the laminated structure may be etched from a top layer to a bottom layer (excluding the substrate 1) by dry etching to expose the capacitor region 100.

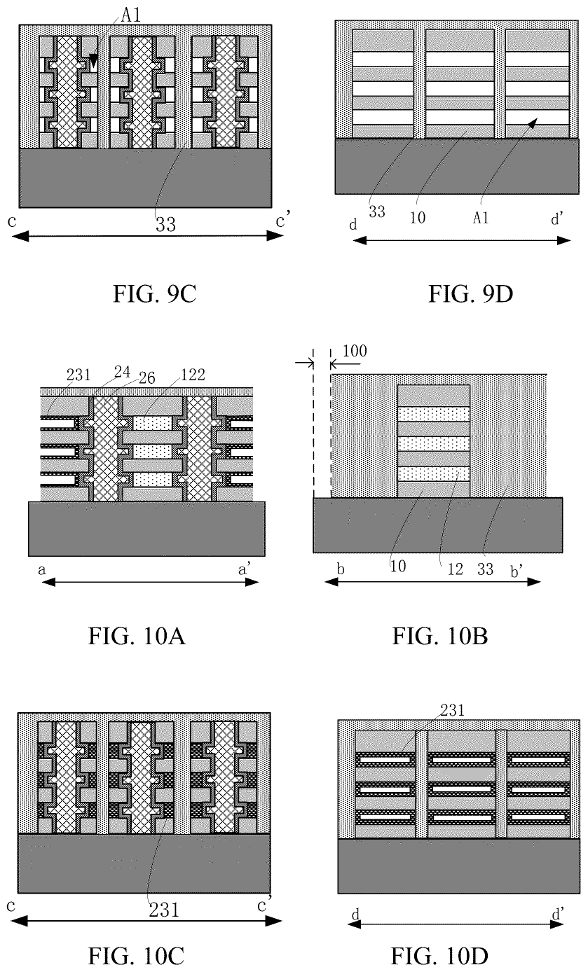

108) Etching a part of the sacrificial layer 12;
The etching the part of the sacrificial layer 12 may include: removing the first sub-part 121 in the sacrificial layer 12 by wet laterally etching based on the first trench T1, and retaining the second sub-part 122 in the sacrificial layer 12; after the first sub-part 121 is etched off, a first lateral groove Al is formed in the region where the first sub-part 121 is located, as shown in FIGS. 9A, 9B, 9C, and 9D. Among them, FIG. 9A is a cross-sectional view along an aa′ direction, FIG. 9B is a cross-sectional view along a bb′ direction, FIG. 9C is a cross-sectional view along a cc′ direction, and FIG. 9D is a cross-sectional view along a dd′ direction.

109) Forming part of the semiconductor layer 23, that is, forming the first semiconductor sub-layer 231;
The forming the part of the semiconductor layer 23 may include: depositing a first semiconductor thin film on the substrate 1 on which the above-mentioned structures are formed, etching and removing the first semiconductor thin film in the capacitor region 100, to form part of the semiconductor layer 23, that is, form the first semiconductor sub-layer 231. The first semiconductor sub-layer 231 may surround part of sidewalls of the gate electrode 26 (for example, surround sidewalls on three sides of the gate electrode 26, and not surround a sidewall facing the second sub-part 122), as shown in FIGS. 10A, 10B, 10C, 10D, and 10E. Among them, FIG. 10A is a cross-sectional view along an aa′ direction, FIG. 10B is a cross-sectional view along a bb′ direction, FIG. 10C is a cross-sectional view along a cc′ direction, FIG. 10D is a cross-sectional view along a dd′ direction, and FIG. 10E is a cross-sectional view along the direction parallel to the substrate 1 (a cross-sectional view of the region where the original sacrificial layer 12 is located). In this step, only part of the semiconductor layer 23 is formed, and another part of the semiconductor layer 23 is to be manufactured subsequently.

In an exemplary embodiment of the present disclosure, a material of the first semiconductor layer 231 may be a material such as silicon or polysilicon with a band gap less than 1.65 eV, or a material with a wide band gap, such as a metal oxide material with a band gap greater than 1.65 eV.

For example, the material of the metal oxide semiconductor layer or channel may include a metal oxide of at least one of the following metals: indium, gallium, zinc, tin, tungsten, magnesium, zirconium, aluminum, hafnium and the like. Of course, compounds containing other elements, such as N, Si and other elements, are not excluded from the metal oxide; and a small amount of other doping elements are also not excluded from the metal oxide.

In some embodiments, the material of the metal oxide semiconductor layer or channel may include one or more of the following: indium gallium zinc oxide (InGaZnO), indium zinc oxide (InZnO), indium gallium oxide (InGaO), indium tin oxide (InSnO), indium gallium tin oxide (InGaSnO), indium gallium zinc tin oxide (InGaZnSnO), indium oxide (InO) , tin oxide (SnO), zinc tin oxide (ZnSnO, ZTO), indium aluminum zinc gold oxide (InAlZnO), zinc oxide (ZnO), indium gallium silicon oxide (InGaSiO), indium tungsten oxide (InWO, IWO), titanium oxide (TiO), zinc oxide (ZnON), magnesium zinc oxide (MgZnO), zirconium indium zinc oxide (ZrInZnO), Hafnium Indium Zinc Oxide (HfInZnO), Tin Indium Zinc Oxide (SnInZnO), Aluminum Tin Indium Zinc Oxide (AlSnInZnO), Silicon Indium Zinc Oxide (SiInZnO), Aluminum Zinc Tin Oxide (AlZnSnO), Gallium Zinc Tin Oxide (GaZnSnO), Zirconium Zinc Tin Oxide (ZrZnSnO), and other materials, as long as a leakage current of transistor can meet requirements, which can be adjusted according to actual situations.

These materials have a wide band gap and a low leakage current. For example, when the metal oxide material is IGZO, the leakage current of the transistor is less than or equal to 10-15 A, thereby improving working performance of the dynamic memory.

The material of the metal oxide semiconductor layer or channel only emphasizes the element type of the material, and does not emphasize an atomic proportion in the material and the thin film quality of the material.

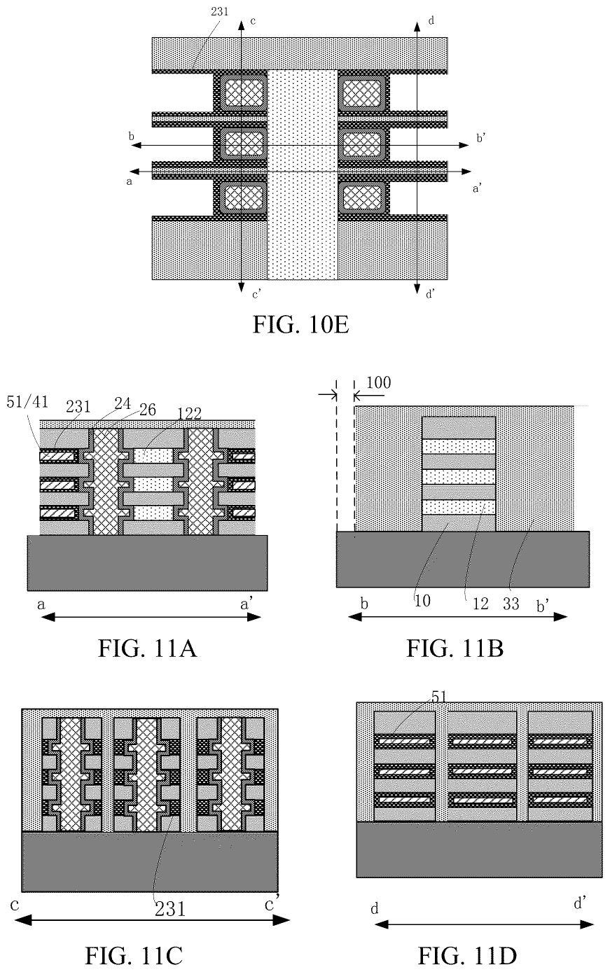

110) Forming a first electrode 51;
The forming the first electrode 51 may include: depositing a first conductive thin film filling the region where the sacrificial layer 12 is located on the substrate 1 on which the above-mentioned structures are formed, that is, depositing a first conductive thin film filling the first lateral groove Al and the first trench T1, etching and removing the first conductive thin film in the capacitor region 100 (that is, etching and removing the first conductive thin film of the first trench T1, retaining the first conductive thin film in the first lateral groove A1, which allows the first conductive thin films of different layers to be disconnected, so that the first electrodes 51 of the transistors of different layers are not connected to each other), forming the first electrode 51. As shown in FIGS. 11A, 11B, 11C, 11D, and 11E, FIG. 11A is a cross-sectional view along an aa′ direction, FIG. 11B is a cross-sectional view along a bb′ direction, FIG. 11C is a cross-sectional view along a cc′ direction, FIG. 11D is a cross-sectional view along a dd′ direction, and FIG. 11E is a cross-sectional view along the direction parallel to the substrate 1 (a cross-sectional view of the region where the original sacrificial layer 12 is located). The first electrode 51 also serves as the first capacitor electrode 41 of the capacitor.

In some embodiments, a material of the first conductive thin film may be one or more of following different types of materials:

For example, a material of the first conductive thin film is a metal, such as tungsten, aluminum, titanium, copper, nickel, platinum, ruthenium, molybdenum, gold, iridium, rhodium, tantalum, cobalt and the like; or may be a metal alloy containing metals of these metals mentioned above.

Or, a material of the first conductive thin film may also be metal oxide, metal nitride, metal silicide and metal carbide, for example, a metal oxide material with high conductivity such as indium tin oxide (ITO), indium zinc oxide (IZO) and indium oxide (InO); for example, the material of the first conductive thin film is a metal nitride material such as titanium nitride (TiN), tantalum nitride (TaN), tungsten nitride (WN) and titanium aluminum nitride (TiAlN).

Optionally, for example, the material of the first conductive thin film may be a polysilicon material, a conductive doped semiconductor, or the like, such as, conductive doped silicon, conductive doped germanium, conductive doped silicon germanium, etc., or another material that shows conductivity, etc.

Materials of subsequent second conductive thin film and the conductive thin film are similar to the first conductive thin film, and will not be repeated here.

In some embodiments, a first type of conductive film may be deposited first, followed by a second type of conductive film, the first type of conductive film may be, for example, TiN, etc., which reduces a contact resistance, and the second type of conductive film may be a conductive material with good conductivity, such as tungsten (W), aluminum (Al), molybdenum (Mo), ruthenium (Ru), titanium (Ti), and tantalum (Ta).

According to the scheme provided by this embodiment, when the semiconductor device is manufactured using different types of first conductive thin films, the process prior to depositing the first conductive thin film is not changed, and only the first conductive thin film is replaced with a corresponding type of conductive thin film when depositing the first conductive thin film, which facilitates the manufacture of transistors using different types of conductive thin films, and reduces costs by eliminating the need for modification of manufacturing processes.

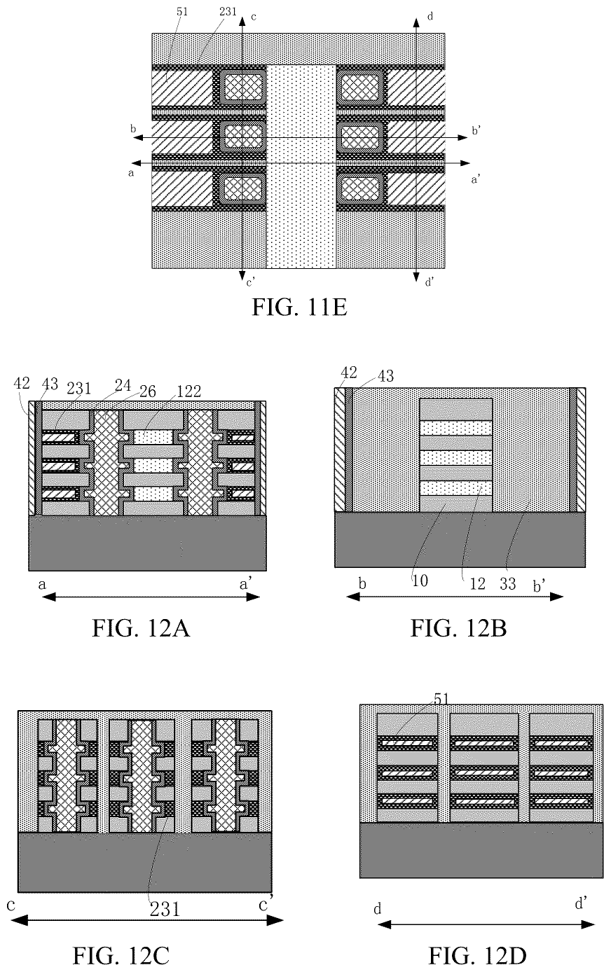

111) Forming a dielectric layer 43 and a second capacitor electrode 42;
The forming the dielectric layer 43 and the second capacitor electrode 42 may include:
   Sequentially depositing a dielectric thin film and a conductor thin film on the substrate 1 on which the above-mentioned structures are formed, to form a dielectric layer 43 and a second capacitor electrode 42 respectively, wherein the dielectric layer 43 covers a sidewall of the first electrode 51 away from the bit line 30, to isolate the first electrode 51 from the second capacitor electrode 42, as shown in FIGS. 12A, 12B, 12C, and 12D. Among them, FIG. 12A is a cross-sectional view along an aa′ direction, FIG. 12B is a cross-sectional view along a bb′ direction, FIG. 12C is a cross-sectional view along a cc′ direction, and FIG. 12D is a cross-sectional view along a dd′ direction.

The dielectric layer 43 serves as a dielectric between capacitor electrodes, the second capacitor electrode 42 serves as one electrode of the capacitor, and the first electrode 51 serves as the other electrode of the capacitor, that is, the first capacitor electrode 41.

In some embodiments, the dielectric thin film and conductor thin film may be deposited by Atomic Layer Deposition (ALD).

In an exemplary embodiment, a material of the dielectric thin film may be a Low-K material, such as silicon oxide, or may be a High-K material, such as a dielectric material with a dielectric constant K≥3.9. In some embodiments, the dielectric thin film may include one or more oxides of hafnium, aluminum, lanthanum, zirconium and the like. For example, the material of the dielectric thin film may include, but is not limited to, at least one of the following: hafnium oxide (HfO2), alumina (Al2O3), hafnium aluminum oxide (HfAlO), hafnium lanthanum oxide (HfLaO), and zirconium oxide (ZrO2), and other high-K materials.

In an exemplary embodiment, the conductor material includes, but is not limited to, at least one of the following or a combination thereof:
A metal or alloy, for example, containing metals such as tungsten, aluminum, titanium, copper, nickel, platinum, ruthenium, molybdenum, gold, iridium, rhodium, tantalum, cobalt, or the like, which may be a metal alloy containing metals of these metals mentioned above.

Optionally, the conductor material may be a metal oxide, a metal nitride, a metal silicide, a metal carbide, etc., such as tin-doped indium oxide (ITO), indium-doped zinc oxide (IZO), indium oxide (InO), aluminum-doped zinc oxide (AZO), iridium oxide (IrOx), ruthenium oxide (RuOx) and other metal oxide conductive materials; for example, titanium nitride (TiN), tantalum nitride (TaN), tungsten nitride (WN), titanium aluminum nitride (TiAlN) and other metal nitride materials.

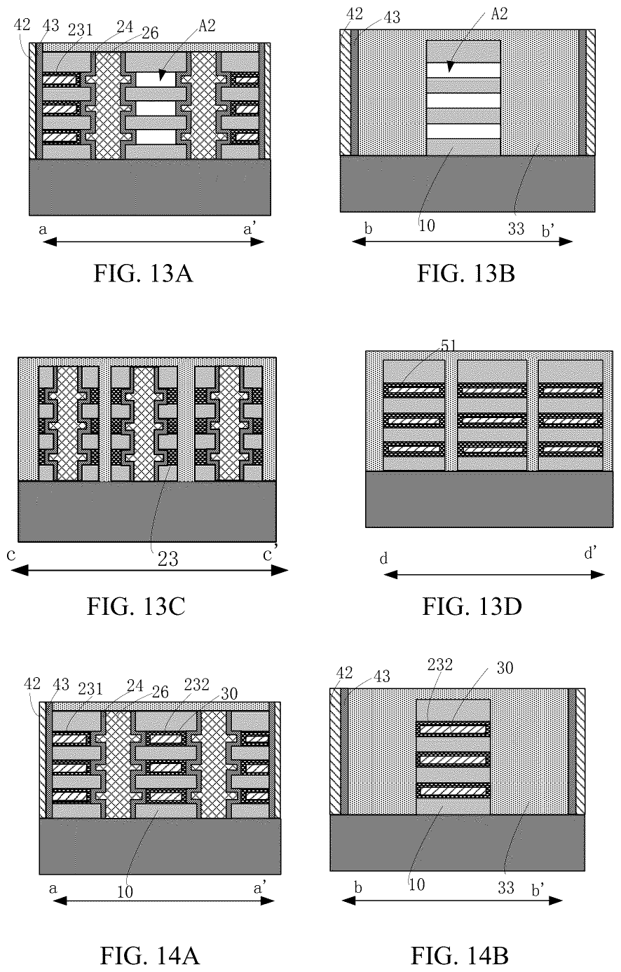

112) Removing the second sub-part 122;
The removing the second sub-part 122 may include: removing the second sub-part 122 by wet laterally etching to form a second lateral groove A2, as shown in FIGS. 13A, 13B, 13C, and 13D. Among them, FIG. 13A is a cross-sectional view along an aa′ direction, FIG. 13B is a cross-sectional view along a bb′ direction, FIG. 13C is a cross-sectional view along a cc′ direction, and FIG. 13D is a cross-sectional view along a dd′ direction.

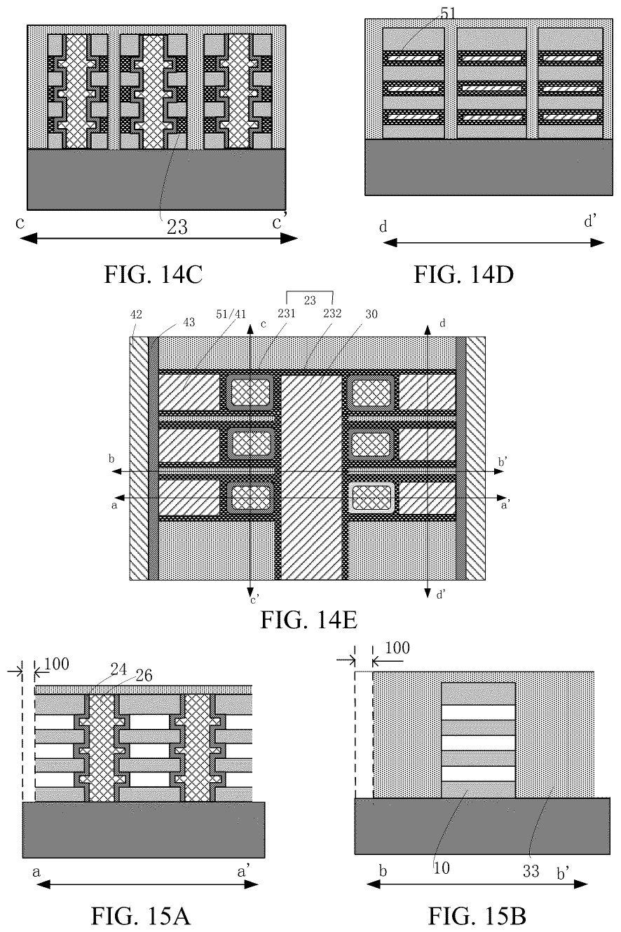

113) Forming another part of the semiconductor layer 23 and a bit line 30, i.e. forming a second semiconductor sub-layer 232 and the bit line 30;
The forming another part of the semiconductor layer 23 and the bit line 30 may include: sequentially depositing a second semiconductor thin film and a second conductive thin film on the substrate 1 on which the above-mentioned structures are formed, to form a second semiconductor sub-layer 232 and a bit line 30, as shown in FIGS. 14A, 14B, 14C, 14D, and 14E. Among them, FIG. 14A is a cross-sectional view along an aa′ direction, FIG. 14B is a cross-sectional view along a bb′ direction, FIG. 14C is a cross-sectional view along a cc′ direction, FIG. 14D is a cross-sectional view along a dd′ direction, and FIG. 14E is a cross-sectional view along the direction parallel to the substrate 1 (a cross-sectional view of a film layer where the bit line 30 is located). The first semiconductor sub-layer 231 and the second semiconductor sub-layer 232 constitute the semiconductor layer 23. The second conductive thin film fills the second lateral groove A2.

It can be seen that the semiconductor layer 23 surrounds the gate electrode 26, and surrounds sidewalls of the bit line 30, and surrounds sidewalls of the first electrode 51 (the first electrode 51 may include a first end face facing the gate electrode 26 and a second end face away from the gate electrode 26, and a sidewall between the first end face and the second end face), the semiconductor layer 23 may be overlaid on the first end face. The bit line 30 may extend in the second direction Y, and the sidewalls of the bit line 30 may be surfaces in the extension direction of the bit line 30.

So far, the manufacture of the semiconductor device has been completed.

In another exemplary embodiment, a manufacturing process of the semiconductor device may include the following step 201) to 220).

201) to 207), same as steps 101) to 107), forming the structure shown in FIGS. 8A to 8D.

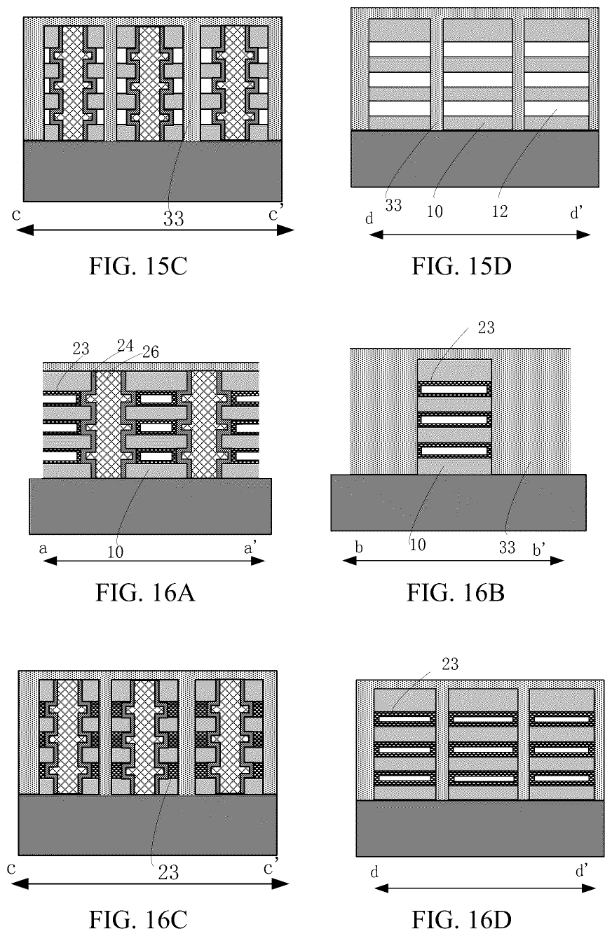

208) Etching the sacrificial layer 12;
The etching the sacrificial layer 12 may include: removing all of the sacrificial layers 12 by wet laterally etching based on the first trench T1, as shown in FIGS. 15A, 15B, 15C, and 15D. Among them, FIG. 15A is a cross-sectional view along an aa′ direction, FIG. 15B is a cross-sectional view along a bb′ direction, FIG. 15C is a cross-sectional view along a cc′ direction, and FIG. 15D is a cross-sectional view along a dd′ direction. It can be seen that all of the sacrificial layers 12 have been removed.

209) Forming a semiconductor layer 23;
The forming the semiconductor layer 23 may include: depositing a semiconductor thin film on the substrate 1 on which the above-mentioned structures are formed, etching and removing the semiconductor thin film in the capacitor region 100 to form the semiconductor layer 23, as shown in FIGS. 16A, 16B, 16C, and 16D. Among them, FIG. 16A is a cross-sectional view along an aa′ direction, FIG. 16B is a cross-sectional view along a bb′ direction, FIG. 16C is a cross-sectional view along a cc′ direction, and FIG. 16D is a cross-sectional view along a dd′ direction.

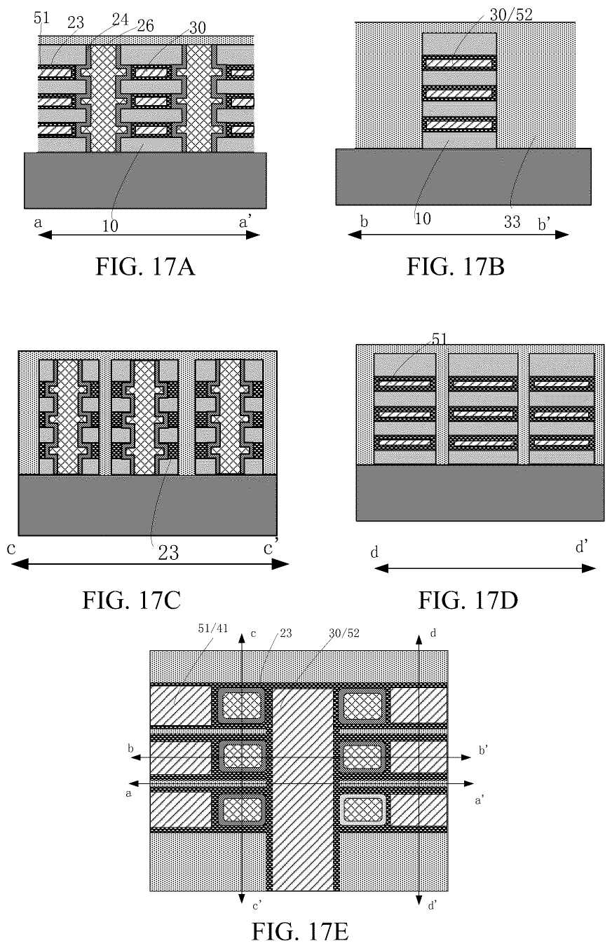

210) Forming a first electrode 51, a second electrode 52, and a bit line 30;
The forming the first electrode 51, the second electrode 52, and the bit line 30 may include: depositing a conductive thin film on the substrate 1 on which the above-mentioned structures are formed, etching and removing the conductive thin film in the first trench T1 to form the first electrode 51, the second electrode 52, and the bit line 30, as shown in FIGS. 17A, 17B, 17C, 17D, and 17E. Among them, FIG. 17A is a cross-sectional view along an aa′ direction, FIG. 17B is a cross-sectional view along a bb′ direction, FIG. 17C is a cross-sectional view along a cc′ direction, FIG. 17D is a cross-sectional view along a dd′ direction, and FIG. 17E is a cross-sectional view along the direction parallel to the substrate 1 (a cross-sectional view of the region where the original sacrificial layer 12 is located). The second electrode 52 and the bit line 30 may be connected to form an integrated structure. The first electrode 51 is also used as the first capacitor electrode 41 of the capacitor. The conductive thin film fills a region where the sacrificial layer 12 etched off in step 209 is located.

According to the scheme provided by the embodiment, when the semiconductor device is manufactured using different types of conductive thin films, the process prior to depositing the conductive thin film is not changed, and only the conductive thin film is replaced with a conductive thin film of a corresponding material when depositing the conductive thin film, which facilitates the manufacture of transistors using conductive thin films of different materials, and reduces costs by eliminating the need for modification of the manufacturing processes.

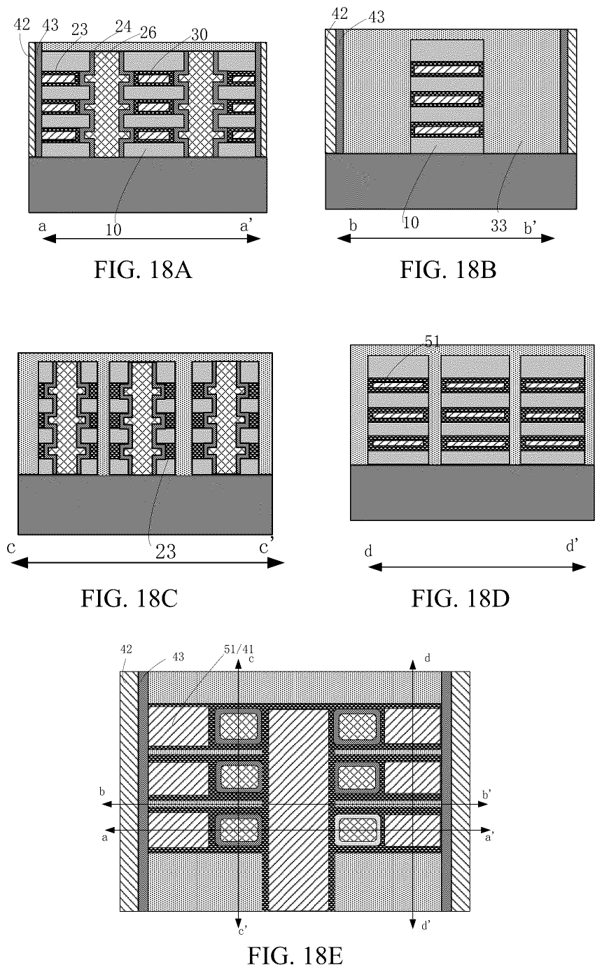

211) Forming a dielectric layer 43 and a second capacitor electrode 42;
The forming the dielectric layer 43 and the second capacitor electrode 42 may include:
   Sequentially depositing a dielectric thin film and a conductor thin film on the substrate 1 on which the above-mentioned structures are formed, to form a dielectric layer 43 and a second capacitor electrode 42 respectively, wherein the dielectric layer 43 covers a sidewall of the first electrode 51 away from the bit line 30, to isolate the first electrode 51 from the second capacitor electrode 42, as shown in FIGS. 18A, 18B, 18C, 18D, and 18E. Among them, FIG. 18A is a cross-sectional view along an aa′ direction, FIG. 18B is a cross-sectional view along a bb′ direction, FIG. 18C is a cross-sectional view along a cc′ direction, FIG. 18D is a cross-sectional view along a dd′ direction, and FIG. 18E is a cross-sectional view along the direction parallel to the substrate 1 after the dielectric layer 43 and the second capacitor electrode 42 are formed (a cross-sectional view of the region where the original sacrificial layer 12 is located).

The dielectric layer 43 serves as a dielectric between capacitor electrodes, the second capacitor electrode 42 serves as one electrode of the capacitor, and the first electrode 51 serves as the other electrode of the capacitor, that is, the first capacitor electrode 41.

In some embodiments, the dielectric thin film and the conductor thin film may be deposited by ALD.

In another exemplary embodiment, a manufacturing process of the semiconductor device may include the following steps.

301) to 309), as in steps 101) to 109), forming the structure shown in FIGS. 10A to 10E.

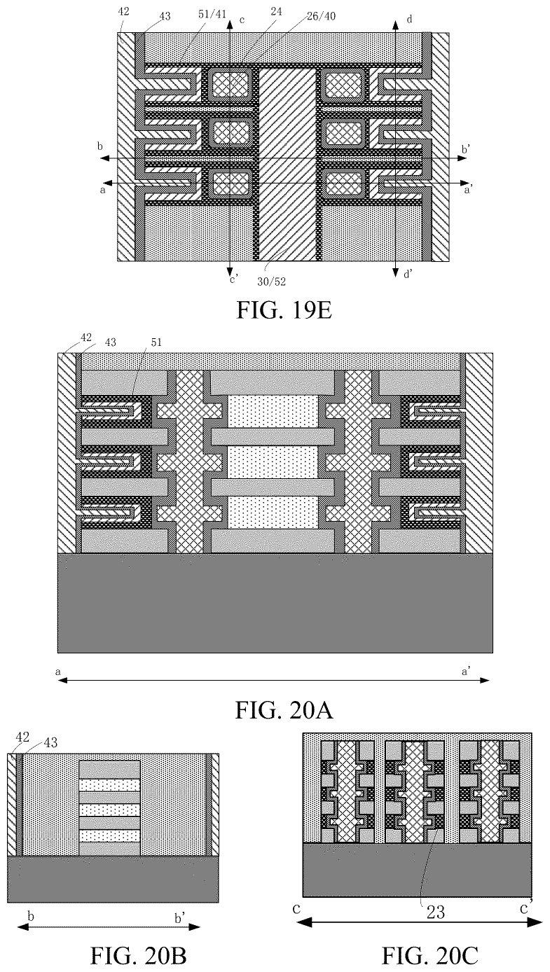

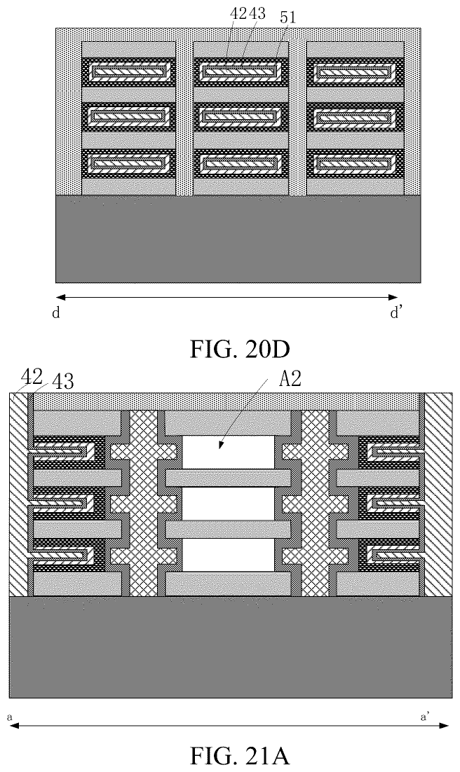

310) Forming a first electrode 51, a dielectric layer 43, and a second capacitor electrode 42;
The forming the first electrode 51, the dielectric layer 43, and the second capacitor electrode 42 may include:
   Depositing a first conductive thin film on the substrate 1 on which the above-mentioned structures are formed, etching and removing the first conductive thin film in the capacitor region 100, that is, etching and removing the first conductive thin film in the first trench T1, to form the first electrode 51; this step may disconnect the first electrodes 51 of transistors of different layers; the first electrode 51 also serves as the first capacitor electrode 41 of the capacitor;
   Sequentially depositing a dielectric thin film and a conductor thin film on the substrate 1 on which the above-mentioned structures are formed, to form a dielectric layer 43 and a second capacitor electrode 42 respectively. The dielectric layer 43 covers a surface of the first electrode 51 away from the bit line 30, and the dielectric layer 43 isolates the first electrode 51 from the second capacitor electrode 42, as shown in FIGS. 20A, 20B, 20C, and 20D. Among them, FIG. 20A is a cross-sectional view along an aa′ direction, FIG. 20B is a cross-sectional view along a bb′ direction, FIG. 20C is a cross-sectional view along a cc′ direction, and FIG. 20D is a cross-sectional view along a dd′ direction. In this embodiment, the second capacitor electrode 42 fills an opening of the first electrode 51, and the first electrode 51 is insulated from the second capacitor electrode 42 through the dielectric layer 43.

In some embodiments, the cross-section of the first electrode 51 in the direction perpendicular to the substrate 1 may be U-shaped, that is, the first electrode 51 has an opening on a side away from the gate electrode 26. That is, in this embodiment, the first electrode 51 does not completely fill the region where the first sub-part 121 is located, and a second groove is formed, and an opening direction of the second groove departs from the gate electrode 26. The first electrode 51 serves as the first capacitor electrode 41 of the capacitor, and compared with a shape of the first electrode 51 without an opening, the shape of the first electrode 51 with the opening can increase the area of the electrode of the capacitor and increase the capacitance value. The second groove can be formed by adjusting a thickness of the sacrificial layer 12 or adjusting a thickness of the deposited first conductive thin film so that the first electrode 51 does not completely fill the region where the first sub-part 121 is located.

In some embodiments, the dielectric thin film and the conductor thin film may be deposited by ALD.

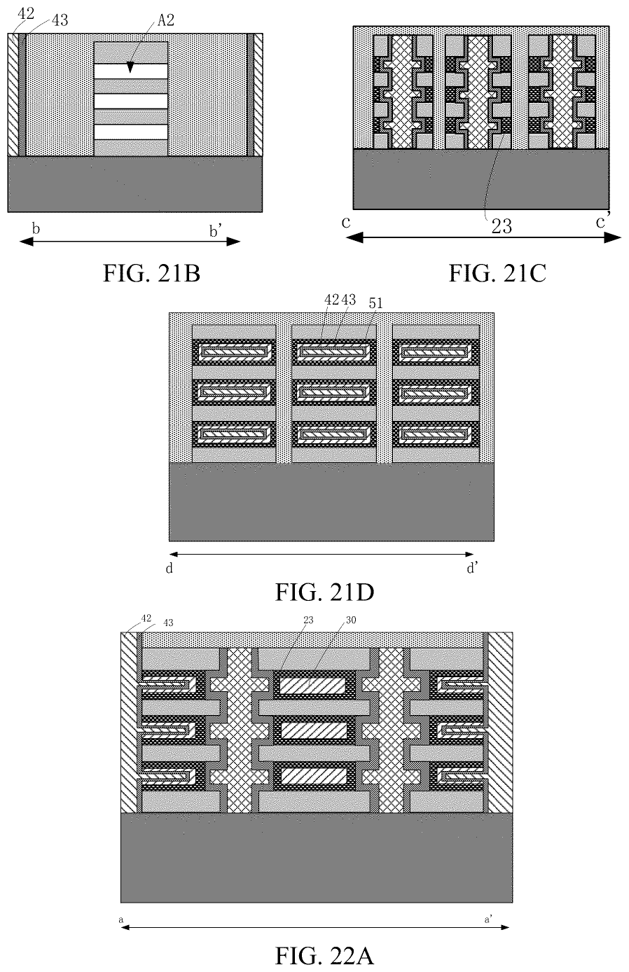

311) Removing the second sub-part 122;
The removing the second sub-part 122 may include: removing the second sub-part 122 by wet etching to form a second lateral groove A2, as shown in FIGS. 21A, 21B, 21C, and 21D. Among them, FIG. 21A is a cross-sectional view along an aa′ direction, FIG. 21B is a cross-sectional view along a bb′ direction, FIG. 21C is a cross-sectional view along a cc′ direction, and FIG. 21D is a cross-sectional view along a dd′ direction.

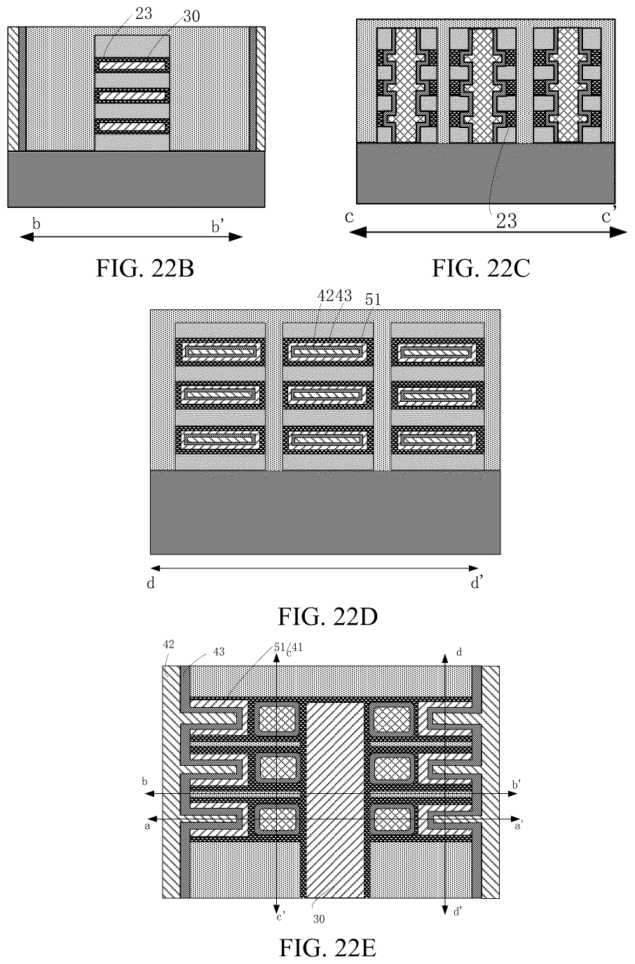

312) Forming another part of the semiconductor layer 23 and a bit line 30, i.e. forming a second semiconductor sub-layer 232;
The forming another part of the semiconductor layer 23 and the bit line 30 may include: sequentially depositing a second semiconductor thin film and a second conductive thin film on the substrate 1 on which the above-mentioned structures are formed, to form a second semiconductor sub-layer 232 and a bit line 30, as shown in FIGS. 22A, 22B, 22C, 22D, and 22E. Among them, FIG. 22A is a cross-sectional view along an aa′ direction, FIG. 22B is a cross-sectional view along a bb′ direction, FIG. 22C is a cross-sectional view along a cc′ direction, FIG. 22D is a cross-sectional view along a dd′ direction, and FIG. 22E is a cross-sectional view along the direction parallel to the substrate 1 (a cross-sectional view of a film layer where the bit line 30 is located). The second conductive thin film fills the region where the second sub-part 122 is located, that is, fills the second lateral groove A2.

An embodiment of the present disclosure further provides an electronic apparatus, which includes the semiconductor device described in any one of the foregoing embodiments. The electronic apparatus may be a storage device, a smart phone, a computer, a tablet computer, an artificial intelligence device, a wearable device or a mobile power supply, etc. The storage device may include a memory in a computer or the like, which is not limited here.

An embodiment of the present disclosure further provides a manufacturing method for a semiconductor device including a plurality of transistors distributed in different layers and stacked along a direction perpendicular to a substrate, a word line extending in the direction perpendicular to the substrate and a bit line; the transistor includes a first electrode, a second electrode, a semiconductor layer surrounding sidewalls of the word line and insulated from the word line; the manufacturing method for the semiconductor device may include:
Providing a substrate, sequentially and alternately depositing first insulating thin films and sacrificial layer thin films on the substrate to form a stacked structure including a plurality of first insulating thin films and a plurality of sacrificial layer thin films;
Forming a through hole penetrating the stacked structure in the direction perpendicular to the substrate, a sidewall of the through hole exposes each of the sacrificial layer thin films, sequentially depositing, in the through hole, gate insulating thin films and gate electrode thin films filling the through hole to form gate insulating layers and word lines of the transistors of multiple layers;
Patterning the stacked structure such that a sacrificial layer forms a preset pattern, the preset pattern includes a first sub-part and a second sub-part connected to the first sub-part, an orthographic projection of the through hole on the substrate is within an outer contour of an orthographic projection of the preset pattern on the substrate, the first sub-part extends in a first direction, the second sub-part extends in a second direction, and the first direction intersects the second direction; and
Etching the first sub-part and etching the second sub-part to form a first semiconductor sub-layer and a first electrode in a region where the first sub-part is located and form a second semiconductor sub-layer and the bit line in a region where the second sub-part is located, the first semiconductor sub-layer and the second semiconductor sub-layer form a semiconductor layer of a transistor, the semiconductor layer surrounds the sidewalls of the word line, the semiconductor layer includes a first groove with an opening facing away from the word line, the first electrode is in the first groove and connected to the semiconductor layer.

In some embodiments, the forming the through hole penetrating the stacked structure in the direction perpendicular to the substrate may include:
Forming a through hole penetrating the stacked structure in the direction perpendicular to the substrate by dry etching, wherein the through hole includes a second sub-hole in the first insulating thin film and a first sub-hole in the sacrificial layer thin film; and
Wet laterally etching the sacrificial layer thin film such that on a plane parallel to the substrate, an orthographic projection of the second sub-hole of the through hole in the first insulating thin film falls into an orthographic projection of the first sub-hole of the through hole in the sacrificial layer thin film.

In some embodiments, the etching the first sub-part and etching the second sub-part to form the first semiconductor sub-layer and the first electrode in the region where the first sub-part is located and form the second semiconductor sub-layer and the second electrode in the region where the second sub-part is located, includes:
Etching and removing the first sub-part and the second sub-part by a single wet etching process;
Sequentially depositing a semiconductor thin film and a conductive thin film in the region where the first sub-part is located and the region where the second sub-part is located to form a semiconductor layer including the first semiconductor sub-layer and the second semiconductor sub-layer, a first electrode, and a bit line.

In some embodiments, the etching the first sub-part and etching the second sub-part to form the first semiconductor sub-layer and the first electrode in the region where the first sub-part is located and form the second semiconductor sub-layer and the second electrode in the region where the second sub-part is located, includes:
Etching and removing the first sub-part, sequentially depositing a first semiconductor thin film and a first conductive thin film in the region where the first sub-part is located to form the first semiconductor sub-layer and the first electrode; and
Etching and removing the second sub-part, and sequentially depositing, in the region where the second sub-part is located, a second semiconductor thin film and a second conductive thin film filling the region where the second sub-part is located to form the second semiconductor sub-layer and the bit line.

In some embodiments, the depositing the first conductive thin film in the region where the first sub-part is located includes:
After the first semiconductor thin film is deposited in the region where the first sub-part is located, depositing the first conductive thin film filling the region where the first sub-part is located on the first semiconductor thin film; or
after the first semiconductor thin film is deposited in the region where the first sub-part is located, depositing a first conductive thin film of a predetermined thickness on the first semiconductor thin film such that the first conductive thin film forms a second groove with an opening facing away from the word line.

Although implementations disclosed in the present disclosure are as the above, the described contents are only implementations used for facilitating understanding the present disclosure, and are not intended to limit the present disclosure. Any person skilled in the art to which the present disclosure pertains may make any modification and variation in the form and details of implementations without facing away from the spirit and the scope disclosed in the present disclosure. Nevertheless, the scope of patent protection of the present disclosure shall still be subject to the scope defined by the appended claims.

1. A semiconductor device, comprising:
a plurality of transistors, distributed in different layers and stacked along a direction perpendicular to a substrate;
a word line, penetrating the different layers and extending in the direction perpendicular to the substrate; and
a transistor comprises a first electrode, a second electrode and a semiconductor layer surrounding a sidewall of the word line; the semiconductor layer comprises a first groove with an opening facing away from the word line, the first electrode is in the first groove and connected to the semiconductor layer, the second electrode is connected to the semiconductor layer, and the first electrode and the second electrode are distributed at intervals in a direction parallel to the substrate.

2. The semiconductor device according to claim 1, wherein a plurality of semiconductor layers of a plurality of transistors in a same column distributed along the direction perpendicular to the substrate are arranged at intervals.

3. The semiconductor device according to claim 1, further comprising: a plurality of bit lines which extend in a second direction parallel to the substrate, are distributed in the different layers and respectively connected to second electrodes of the plurality of transistors; and the semiconductor layer of the transistor also surrounds a sidewall of a bit line to which the transistor is connected.

4. The semiconductor device according to claim 3, wherein the semiconductor layer of the transistor is further connected to an end face of the bit line to which the transistor is connected.

5. The semiconductor device according to claim 3, wherein the second electrode and the bit line are connected to form an integrated structure.

6. The semiconductor device according to claim 3, wherein further comprising a gate insulating layer disposed between the sidewall of the word line and the semiconductor layer, and gate insulating layers of a plurality of transistors in a same column distributed along the direction perpendicular to the substrate are connected to form an integrated structure.

7. The semiconductor device according to claim 6, wherein further comprising:
insulating layers and conductive layers sequentially and alternately distributed from bottom to top in the direction perpendicular to the substrate, wherein a conductive layer comprises the first electrode and the second electrode; and
a through hole penetrating each of the insulating layers and each of the conductive layers, wherein the word line and the gate insulating layer surrounding the sidewall of the word line are sequentially distributed in the through hole from inside to outside.

8. The semiconductor device according to claim 7, wherein an aperture of a first region of the through hole corresponding to the conductive layer is larger than an aperture of a second region of the through hole corresponding to an insulating layer; and
only a sidewall of the conductive layer is exposed in the through hole, and a sidewall and partial regions of upper and lower surfaces of the insulating layer are exposed in the through hole.

9. The semiconductor device according to claim 1, wherein the first electrode comprises a second groove with an opening facing away from the word line.

10. The semiconductor device according to claim 9, wherein the semiconductor device further comprises a second capacitor electrode filling the second groove of the first electrode, and a dielectric layer disposed between the second capacitor electrode and the first electrode.

11. The semiconductor device according to claim 1, wherein the semiconductor device further comprises a second capacitor electrode, and a dielectric layer disposed between the second capacitor electrode and the first electrode, a contact surface between the dielectric layer and the first electrode is perpendicular to the substrate.

12. An electronic apparatus, comprising the semiconductor device according to claim 1.

13. A manufacturing method for a semiconductor device, wherein the semiconductor device comprises a plurality of transistors distributed in different layers and stacked along a direction perpendicular to a substrate, a word line extending in the direction perpendicular to the substrate and a bit line; a transistor comprises a first electrode, a second electrode, and a semiconductor layer surrounding a sidewall of the word line and insulated from the word line; and the manufacturing method for the semiconductor device comprises:
providing the substrate, sequentially and alternately depositing a first insulating thin film and a sacrificial layer thin film on the substrate to form a stacked structure comprising a plurality of first insulating layers and a plurality of sacrificial layers;
forming a through hole penetrating the stacked structure in the direction perpendicular to the substrate, a sidewall of the through hole exposing each of the sacrificial layer thin films, sequentially depositing, in the through hole, a gate insulating thin film and a gate electrode thin film filling the through hole to form gate insulating layers and word lines of the transistors of a plurality of layers;
patterning the stacked structure such that a sacrificial layer forms a preset pattern, the preset pattern comprises a first sub-part and a second sub-part connected to the first sub-part, an orthographic projection of the through hole on the substrate is within an outer contour of an orthographic projection of the preset pattern on the substrate, the first sub-part extends in a first direction, the second sub-part extends in a second direction, and the first direction intersects the second direction; and
etching the first sub-part and etching the second sub-part to form a first semiconductor sub-layer and the first electrode in a region where the first sub-part is located and form a second semiconductor sub-layer and the bit line in a region where the second sub-part is located, wherein the first semiconductor sub-layer and the second semiconductor sub-layer form the semiconductor layer of the transistor, the semiconductor layer surrounds the sidewall of the word line, the semiconductor layer comprises a first groove with an opening facing away from the word line, the first electrode is in the first groove and connected to the semiconductor layer.

14. The manufacturing method for the semiconductor device according to claim 13, wherein forming the through hole penetrating the stacked structure in the direction perpendicular to the substrate comprises:
forming the through hole penetrating the stacked structure in the direction perpendicular to the substrate by dry etching, wherein the through hole comprises a second sub-hole in a first insulating layer and a first sub-hole in a sacrificial layer; and
wet laterally etching the sacrificial layer such that on a plane parallel to the substrate, an orthographic projection of the second sub-hole of the through hole in the first insulating layer falls into an orthographic projection of the first sub-hole of the through hole in the sacrificial layer.

15. The manufacturing method for the semiconductor device according to claim 13, wherein,
the etching the first sub-part and etching the second sub-part to form the first semiconductor sub-layer and the first electrode in the region where the first sub-part is located and form the second semiconductor sub-layer and the second electrode in the region where the second sub-part is located comprises:
etching and removing the first sub-part and the second sub-part by a single wet etching process; and
sequentially depositing a semiconductor thin film and a conductive thin film in the region where the first sub-part is located and the region where the second sub-part is located to form the semiconductor layer comprising the first semiconductor sub-layer and the second semiconductor sub-layer, the first electrode, and the bit line.

16. The manufacturing method for the semiconductor device according to claim 13, wherein the etching the first sub-part and etching the second sub-part to form the first semiconductor sub-layer and the first electrode in the region where the first sub-part is located and form the second semiconductor sub-layer and the second electrode in the region where the second sub-part is located comprises:
etching and removing the first sub-part, sequentially depositing a first semiconductor thin film and a first conductive thin film in the region where the first sub-part is located to form the first semiconductor sub-layer and the first electrode; and
etching and removing the second sub-part, and sequentially depositing, in the region where the second sub-part is located, a second semiconductor thin film and a second conductive thin film filling the region where the second sub-part is located to form the second semiconductor sub-layer and the bit line.

17. The manufacturing method for the semiconductor device according to claim 16, wherein the depositing the first conductive thin film in the region where the first sub-part is located comprises:
after the first semiconductor thin film is deposited in the region where the first sub-part is located, depositing the first conductive thin film filling the region where the first sub-part is located on the first semiconductor thin film; or
after the first semiconductor thin film is deposited in the region where the first sub-part is located, depositing the first conductive thin film of a predetermined thickness on the first semiconductor thin film such that the first conductive thin film forms a second groove with an opening facing away from the word line.
